(19) United States
(12) Patent Application Publication
(10) Pub. No.: US 2025/0366327 A1
(43) Pub. Date: Nov. 27, 2025

(54) SUB-PIXEL AND DISPLAY DEVICE INCLUDING THE SAME

(71) Applicant: Samsung Display Co., LTD., Yongin-si (KR)

(72) Inventor: Gi Chang LEE, Yongin-si (KR)

(21) Appl. No.: 19/074,667

(22) Filed: Mar. 10, 2025

(30) Foreign Application Priority Data
May 23, 2024 (KR) 10-2024-0067341

(51) Int. Cl. H10K 59/131

(52) U.S. Cl. CPC H10K 59/131

(57) ABSTRACT

A sub-pixel includes a sixth transistor including a gate, a source electrode, and a drain electrode, wherein the gate is connected to one of a second transistor and a second node, and wherein the source electrode and the drain electrode are connected to the other of the second transistor and the second node. The sub-pixel further includes a seventh transistor including a gate, a source electrode, and a drain electrode, wherein the gate is connected to one of the second node and a fourth power line, and wherein the source electrode and the drain electrode are connected to the other of the second node and the fourth power line.

This application claims priority to Korean Patent Application No. 10-2024-0067341,filed on May 23, 2024, and all the benefits accruing therefrom under 35 U.S.C. § 119, the content of which in its entirety is herein incorporated by reference.

### BACKGROUND

### 1. Field of the Invention

The invention relates to a sub-pixel, and more particularly to a sub-pixel and a display device including the same.

### 2. Description of the Related Art

As information technology develops, the importance of display devices, which are a connection medium between users and information, is emerging. Accordingly, the use of display devices, such as a liquid crystal display device, an organic light emitting display device, and the like has been increasing.

Additionally, a sub-pixel displaying an image in a display device may be provided with a capacitor for various purposes. The capacitor may typically be formed through a process that is separate from a process that forms a transistor. For example, a method of first forming one electrode of the capacitor together with the transistor and then forming the other electrode of the capacitor may be adopted.

However, when the transistor and the capacitor are formed through separate processes as described above, an additional mask for forming the capacitor is required, and additional time for forming the capacitor may be required.

### SUMMARY

The present invention includes a sub-pixel including a transistor that may perform the function of a capacitor and a display device including the same.

In an embodiment a sub-pixel including a light emitting element connected between a first node and a second power line, a first transistor connected between a first power line and the first node and including a gate connected to a second node, a second transistor connected to a data line and including a gate connected to a first scan line, a third transistor connected between the first node and the second node and including a gate connected to a second scan line, a fourth transistor connected between the first node and the light emitting element and including a gate connected to a light emitting control line, a fifth transistor connected between the fourth transistor and a third power line and including a gate connected to a third scan line, a sixth transistor including a gate, a source electrode, and a drain electrode, wherein the gate is connected to one of the second transistor and the second node, and the source electrode and the drain electrode are connected to the other of the second transistor and the second node, and a seventh transistor including a gate, a source electrode, and a drain electrode, wherein the gate is connected to one of the second node and a fourth power line, and wherein the source electrode and the drain electrode are connected to the other of the second node and the fourth power line.

In an embodiment, the first to fifth transistors may include a P-type semiconductor layer.

In an embodiment, the sixth transistor may include a P-type semiconductor layer.

In an embodiment, the sixth transistor may include an N-type semiconductor layer.

In an embodiment, the seventh transistor may include a P-type semiconductor layer.

In an embodiment, the seventh transistor may include an N-type semiconductor layer.

In an embodiment, each of the first to seventh transistors may include a semiconductor layer formed on a silicon substrate.

In an embodiment, a thickness of a gate insulating layer which is disposed between the gate of the first transistor and the semiconductor layer of the first transistor may be thicker than that of a gate insulating layer which is disposed between the gate of at least one of the second to seventh transistors and the semiconductor layer thereof.

In an embodiment, the semiconductor layer of each of the first to fifth transistors may be disposed in an N-well.

In an embodiment, the semiconductor layer of each of the sixth and seventh transistors may be disposed in an N-well.

In an embodiment, the semiconductor layer of at least one of the sixth transistor and the seventh transistor may be disposed in a P-well.

In an embodiment, the N-well may be deeper than the P-well.

In an embodiment, a (1-1)-th power voltage may be applied to the first power line, and a second power voltage may be applied to the second power line. A level of the (1-1)-th power voltage may be higher than that of the second power voltage.

In an embodiment, a (1-2)-th power voltage that is higher than the second power voltage may be applied to the fourth power line.

In an embodiment, an initialization voltage may be applied to the third power line and an initialization voltage may be applied to the fourth power line.

In an embodiment a display device includes a display panel in which a plurality of sub-pixels are disposed on a substrate and a plurality of data lines connected to the plurality of sub-pixels are disposed and a data driver configured to supply a reference voltage or a data signal to the plurality of data lines, wherein at least one of the plurality of sub-pixels includes a light emitting element connected between a first node and a second power line, a first transistor connected between a first power line and the first node and including a gate connected to a second node, a second transistor connected to one of the plurality of data lines and including a gate connected to a first scan line, a third transistor connected between the first node and the second node and including a gate connected to a second scan line, a fourth transistor connected between the first node and the light emitting element and including a gate connected to a light emitting control line, a fifth transistor connected between the fourth transistor and a third power line and including a gate connected to a third scan line, a sixth transistor including a gate, a source electrode, and a drain electrode, wherein the gate is connected to one of the second transistor and the second node, and wherein the source electrode and the drain electrode are connected to the other of the second transistor and the second node and a seventh transistor including a gate, a source electrode, and a drain electrode, wherein the gate is connected to one of the second node and a fourth power line, and wherein the source electrode and the drain electrode are connected to the other of the second node and the fourth power line.

In an embodiment, the display panel may include a substrate including a semiconductor layer, a gate insulating layer disposed on the substrate and a gate electrode disposed to overlap a channel area of the semiconductor layer. The gate of each of the first to seventh transistors may include a gate electrode.

In an embodiment, each of the first to seventh transistors may include a P-type semiconductor layer.

In an embodiment, each of the first to fifth transistors and the seventh transistor may include a P-type semiconductor layer. The sixth transistor may include an N-type semiconductor layer.

In an embodiment, each of the first to sixth transistors may include a P-type semiconductor layer. The seventh transistor may include an N-type semiconductor layer.

### BRIEF DESCRIPTION OF THE DRAWINGS

FIG. 1 illustrates a block diagram of a display device, according to an embodiment.

FIG. 2 illustrates a schematic block diagram of one of sub-pixels of FIG. 1,

according to an embodiment.

FIG. 3 illustrates an equivalent circuit diagram of the sub-pixel of FIG. 2, according to an embodiment.

FIG. 4 illustrates an example of a driving timing diagram of a sub-pixel, according to an embodiment.

FIG. 5 is a circuit diagram and a timing diagram for describing the equivalent circuit diagram of FIG. 3 and the driving timing diagram of FIG. 4, according to an embodiment.

FIG. 6 is a circuit diagram and a timing diagram for describing the equivalent circuit diagram of FIG. 3 and the driving timing diagram of FIG. 4, according to an embodiment.

FIG. 7 is a circuit diagram and a timing diagram for describing the equivalent circuit diagram of FIG. 3 and the driving timing diagram of FIG. 4, according to an embodiment.

FIG. 8 is a circuit diagram and a timing diagram for describing the equivalent circuit diagram of FIG. 3 and the driving timing diagram of FIG. 4, according to an embodiment.

FIG. 9 schematically illustrates a semiconductor layer and a gate of each of a first type transistor and a second type transistor of FIG. 3, according to an embodiment.

FIG. 10 is block diagram that illustrates a step of forming the gate of each of the first and second type transistors of FIG. 9, according to an embodiment.

FIG. 11 is block diagram that illustrates a step of forming the gate of each of the first and second type transistors of FIG. 9, according to an embodiment.

FIG. 12 is block diagram that illustrates a step of forming the gate of each of the first and second type transistors of FIG. 9, according to an embodiment.

FIG. 13 is block diagram that illustrates a step of forming the gate of each of the first and second type transistors of FIG. 9, according to an embodiment.

FIG. 14 is block diagram that illustrates a step of forming the gate of each of the first and second type transistors of FIG. 9, according to an embodiment.

FIG. 15 is block diagram that illustrates a step of forming the gate of each of the first and second type transistors of FIG. 9, according to an embodiment.

FIG. 16 is block diagram that illustrates a step of forming the gate of each of the first and second type transistors of FIG. 9, according to an embodiment.

FIG. 17 is block diagram that illustrates a step of forming the gate of each of the first and second type transistors of FIG. 9, according to an embodiment.

FIG. 18 is block diagram that illustrates a step of forming the gate of each of the first and second type transistors of FIG. 9, according to an embodiment.

FIG. 19 is block diagram that illustrates a step of forming the gate of each of the first and second type transistors of FIG. 9, according to an embodiment.

FIG. 20 is block diagram that illustrates a step of forming the gate of each of the first and second type transistors of FIG. 9, according to an embodiment.

FIG. 21 is an equivalent circuit diagram of the sub-pixel of FIG. 2, according to another embodiment.

FIG. 22 schematically illustrates a semiconductor layer and a gate of each of a first type transistor, a second type transistor, and a third type transistor of FIG. 21, according to an embodiment.

FIG. 23 illustrates an equivalent circuit diagram of the sub-pixel of FIG. 2, according to another embodiment.

FIG. 24 schematically illustrates a semiconductor layer and a gate of each of a first type transistor, a second type transistor, and a third type transistor of FIG. 23, according to an embodiment.

FIG. 25 illustrates a top plan view of a display panel of FIG. 1, according to an embodiment.

FIG. 26 illustrates an exploded perspective view of a portion of the display panel of FIG. 25, according to an embodiment.

FIG. 27 illustrates a top plan view of one of pixels of FIG. 26, according to an embodiment.

FIG. 28 illustrates a vertical cross-sectional view taken along line I-I′ of FIG. 27, according to an embodiment.

FIG. 29 illustrates a cross-sectional view of a light emitting structure included in one of the first to third light emitting elements of FIG. 28, according to an embodiment.

FIG. 30 illustrates a cross-sectional view of a light emitting structure included in one of the first to third light emitting elements of FIG. 28, according to another embodiment.

FIG. 31 illustrates a top plan view of one of the pixels of FIG. 26, according to another embodiment.

FIG. 32 illustrates a top plan view of one of pixels of FIG. 26, according to another embodiment.

FIG. 33 illustrates a block diagram of a display system, according to an embodiment.

FIG. 34 illustrates a perspective view of an application example of the display system of FIG. 33, according to an embodiment.

FIG. 35 illustrates a head-mounted display device worn on a user, according to an embodiment.

### DETAILED DESCRIPTION

Hereinafter, example embodiments of the invention will be described in detail with reference to the accompanying drawings. The following description is intended to provide only a sufficient disclosure to enable the understanding of the operation of the invention, and any other disclosure is omitted to avoid obscuring the scope of the invention. In addition, the invention may be embodied in different forms and is not limited to the embodiments set forth herein. The embodiments described herein are provided for the purpose of describing the technical concept of the invention in sufficient detail for those skilled in the art to easily practice it.

Throughout the specification, when it is described that an element is “connected” to another element, this includes not only being “directly connected”, but also being “indirectly connected” with another device in between. The terms used herein are for the purpose of describing specific embodiments and are not intended to limit the scope of the invention. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

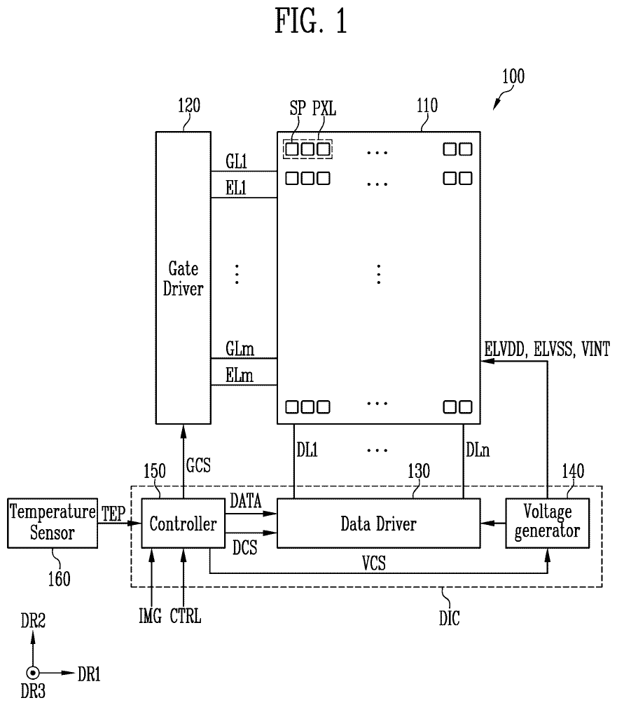

FIG. 1 illustrates a block diagram of a display device 100, according to an embodiment.

In an embodiment and referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm, respectively. The sub-pixels SP may be connected to the data driver 130 through first to n-th data lines DL1 to DLn, respectively.

In an embodiment, each of the sub-pixels SP may include at least one light emitting element configured to generate light. Accordingly, the sub-pixels SP may respectively generate light of a specific color, such as red, green, blue, cyan, magenta, yellow, or the like. Two or more of the sub-pixels SP may configure one pixel PXL. For example, as shown in FIG. 1, three sub-pixels may configure one pixel PXL.

In an embodiment, the gate driver 120 is connected to the sub-pixels SP which are arranged in a row direction through the gate lines GL1 to GLm. The gate driver 120 may output gate signals to the gate lines GL1 to GLm in response to a gate control signal GCS. In an embodiment, the gate control signal GCS may include a start signal indicating the start of each frame, a horizontal synchronization signal for outputting gate signals in synchronization with the timing at which data signals are applied, and the like.

In some embodiments, light emitting control lines EL1 to ELm connected to the sub-pixels SP in a row direction may be further provided. In this case, the gate driver 120 may include a light emitting control driver configured to control the light emitting control lines EL1 to ELm, and the light emitting control driver may operate under the control of the controller 150.

In an embodiment, the gate driver 120 may be disposed on one side of the display panel 110. However, the invention is not limited thereto. For example, the gate driver 120 may be divided into two or more physically and/or logically separated drivers, where the drivers may be disposed on one side of the display panel 110 and the other side of the display panel 110 opposite to the one side. As described above, the gate driver 120 may be disposed around the display panel 110 in various forms according to the embodiments.

In an embodiment, the data driver 130 is connected to the sub-pixels SP which are arranged in a column direction through the data lines DL1 to DLn. The data driver 130 receives image data (DATA) and data control signal DCS from the controller 150. The data driver 130 operates in response to the data control signal DCS. In an embodiment, the data control signal DCS may include a source start pulse signal, a source shift clock signal, a source output enable signal, and the like.

In an embodiment, the data driver 130 may use voltages from the voltage generator 140 to apply data signals having grayscale voltages corresponding to the image data DATA to the data lines DL1 to DLn. When a gate signal is applied to each of the gate lines GL1 to GLm, data signals corresponding to the image data DATA may be applied to the data lines DL1 to DLn. Accordingly, the corresponding sub-pixels SP may generate light corresponding to the data signals. Accordingly, an image is displayed on the display panel 110.

In an embodiment, the gate driver 120 and the data driver 130 may include complementary metal-oxide semiconductor (CMOS) circuit elements.

In an embodiment, the voltage generator 140 may operate in response to a voltage control signal VCS from the controller 150, where the voltage generator 140 is configured to generate a plurality of voltages and provide the generated voltages to constituent elements of the display device 100. For example, the voltage generator 140 may be configured to generate a plurality of voltages by receiving an input voltage from outside of the display device 100, adjusting the received voltage, and regulating the adjusted voltage.

The voltage generator 140 may generate a first power voltage ELVDD, a second power voltage ELVSS, and an initialization voltage VINT. The first and second power voltages ELVDD and ELVSS and the initialization voltage VINT generated by the voltage generator 140 may be provided to the sub-pixels SP. The first power voltage ELVDD may have a relatively high voltage level, and the second power voltage ELVSS and the initialization voltage VINT may have a voltage level that is lower than the first power voltage ELVDD. In other embodiments, the first power voltage ELVDD or the second power voltage ELVSS may be provided by an external device of the display device 100.

In addition, the voltage generator 140 may generate various voltages. For example, the voltage generator 140 may generate an initialization voltage which may be applied to the sub-pixels SP. For example, during a sensing operation to sense electrical characteristics of transistors and/or light emitting elements of the sub-pixels SP, a predetermined reference voltage may be applied to the data lines DL1 to DLn, and the voltage generator 140 may generate the reference voltage.

In an embodiment, the controller 150 controls various operations of the display device 100. The controller 150 receives input image data IMG and a control signal CTRL for controlling the display of the input image data, from the outside. The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In an embodiment, the controller 150 may output the image data DATA by aligning the input image data IMG to be suitable for the sub-pixels SP of a row unit.

In an embodiment, two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, and the controller 150 may be provided as a component separated from the driver integrated circuit DIC.

In an embodiment, the display device 100 may include at least one temperature sensor 160, where the temperature sensor 160 is configured to sense a surrounding temperature and generate temperature data TEP representing the sensed temperature. In an embodiment, the temperature sensor 160 may be disposed to be located adjacent to the display panel 110 and/or the driver integrated circuit DIC.

In an embodiment, the controller 150 may control various operations of the display device 100 in response to the temperature data TEP. In an embodiment, the controller 150 may adjust the luminance of an image outputted from the display panel 110 in response to the temperature data TEP. For example, the controller 150 may control the data signals and the power voltages ELVDD and ELVSS by controlling components such as the data driver 130 and/or the voltage generator 140.

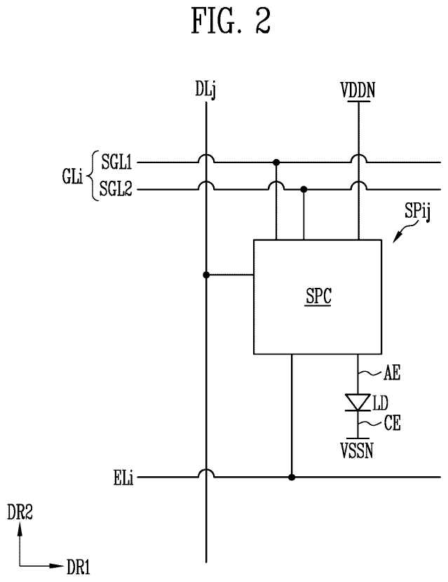

FIG. 2 illustrates a block diagram of one of the sub-pixels SP of FIG. 1, according to an embodiment.

In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

In an embodiment and referring to FIG. 2, the sub-pixel SPij may include a sub-pixel circuit SPC and a light emitting element LD.

In an embodiment, the light emitting element LD is connected between the first power voltage node VDDN and a second power voltage node VSSN. In this case, the first power voltage node VDDN is a node that transmits the first power voltage ELVDD of FIG. 1, and the second power voltage node VSSN is a node that transmits the second power voltage ELVSS of FIG. 1.

In an embodiment, an anode electrode AE of the light emitting element LD may be connected to the first power voltage node VDDN through the sub-pixel circuit

SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

In an embodiment, the sub-pixel circuit SPC may be connected to an i-th gate line GLi among the gate lines GL1 to GLm of FIG. 1, an i-th light emitting control line ELi among the light emitting control lines EL1 to ELm of FIG. 1, and a j-th data line DLj among the data lines DL1 to DLn of FIG. 1. The sub-pixel circuit SPC is configured to control the light emitting element LD according to signals received through these signal lines.

The sub-pixel circuit SPC may operate in response to a gate signal received through the i-th gate line GLi, where the i-th gate line GLi may include one or more sub-gate lines. In an embodiment, as shown in FIG. 2, the i-th gate line GLi may include first and second sub-gate lines SGL1 and SGL2, respectively. The sub-pixel circuit SPC may operate in response to gate signals received through the sub-gate lines SGL1 and SGL2. As such, when the i-th gate line GLi includes two or more sub-gate lines, the sub-pixel circuit SPC may operate in response to gate signals received through the corresponding sub-gate lines.

The sub-pixel circuit SPC may operate in response to a light emitting control signal received through the i-th light emitting control line ELi. In an embodiment, the i-th light emitting control line ELi may include one or more sub-light emitting control lines. When the i-th light emitting control line ELi includes two or more sub-light emitting control lines, the sub-pixel circuit SPC may operate in response to light emitting control signals received through the corresponding sub-light emitting control lines.

The sub-pixel circuit SPC may receive a data signal through the j-th data line DLj. The sub-pixel circuit SPC may store a voltage corresponding to the data signal in response to at least one of the gate signals received through the sub-gate lines SGL1 and SGL2. In response to the light emitting control signal received through the i-th light emitting control line ELi, the sub-pixel circuit SPC may adjust the current flowing from the first power voltage node VDDN to the second power voltage node VSSN through the light emitting element LD according to the stored voltage. Accordingly, the light emitting element LD may generate light of luminance corresponding to the data signal.

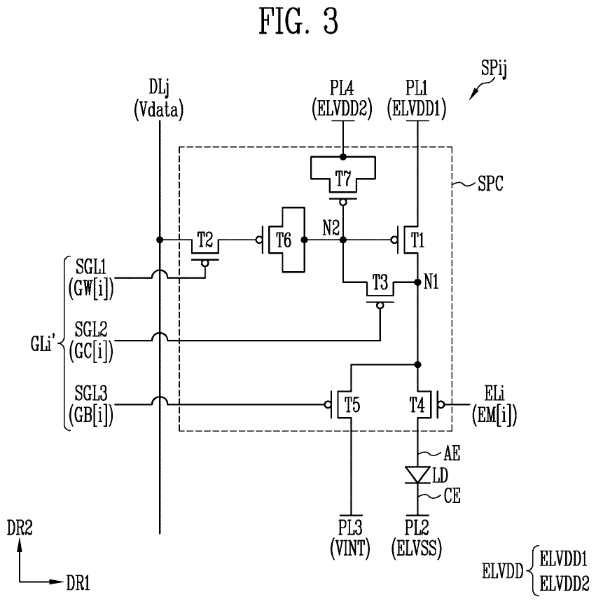

FIG. 3 illustrates an equivalent circuit diagram of the sub-pixel SPij of FIG. 2, according to an embodiment.

In an embodiment and referring to FIG. 3, the sub-pixel SPij may include a sub-pixel circuit SPC and a light emitting element LD.

In an embodiment, the sub-pixel circuit SPC may be connected to an i-th gate line GLi′, an i-th light emitting control line ELi, and a j-th data line DLj. Compared to the i-th gate line GLi of FIG. 2, the i-th gate line GLi′ may further include a third sub-gate line SGL3.

In an embodiment, the sub-pixel circuit SPC may include first to seventh transistors T1 to T7, respectively.

In an embodiment, the first transistor T1 may be connected between a first power line PL1 and a first node N1. A node to which the first transistor T1 and the first power line PL1 are connected may correspond to the first power voltage node VDDN of FIG. 2. A gate of the first transistor T1 may be connected to a second node N2. An amount of current flowing through the first transistor T1 may be controlled depending on a voltage level applied to the second node N2. The first transistor T1 may be referred to as a driving transistor.

In an embodiment, the first power voltage ELVDD may be applied to the first power line PL1. In an embodiment, a (1-1)-th power voltage ELVDD1 may be applied to the first power line PL1.

In an embodiment, the second transistor T2 is connected to the j-th data line DLj. In the embodiment, the second transistor T2 may be connected between the j-th data line DLj and a gate of the sixth transistor T6. In another embodiment, the second transistor T2 may be connected between the j-th data line DLj and a source electrode and a drain electrode of the sixth transistor. A gate of the second transistor T2 may be connected to the first sub-gate line SGL1. An operation timing of the second transistor T2 may be controlled in response to a first gate signal GW[i] that is applied to the first sub-gate line SGL1. The second transistor T2 may be referred to as a switching transistor.

In an embodiment, the third transistor T3 is connected between the first node N1 and the second node N2 and a gate of the third transistor T3 may be connected to the second sub-gate line SGL2. An operation timing of the third transistor T3 may be controlled in response to a second gate signal GC[i] applied to the second sub-gate line SGL2.

In an embodiment, the fourth transistor T4 is connected of between the first node N1 and the anode electrode AE of the light emitting element LD. A gate of the fourth transistor T4 may be connected to the i-th light emitting control line ELi. An operation timing of the fourth transistor T4 may be controlled in response to a light emitting control signal EM[i] applied to the i-th light emitting control line ELi.

In an embodiment, the fifth transistor T5 may be connected between the fourth transistor T4 and a third power line PL3. In an embodiment, the fifth transistor T5 may be connected between the first node N1 and the third power line PL3. In an embodiment, the fifth transistor T5 may be connected between the anode electrode AE and the third power line PL3. The initialization voltage VINT may be applied to the third power line PL3. In an embodiment, the initialization voltage VINT may be provided by the voltage generator 140 of FIG. 1. In other embodiments, the initialization voltage may be provided by an external device to the display device 100. A gate of the fifth transistor T5 may be connected to the third sub-gate line SGL3. An operation timing of the fifth transistor T5 may be controlled in response to a third gate signal GB[i] applied to the third sub-gate line SGL3.

In an embodiment, the sixth transistor T6 may include a gate, a source electrode, and a drain electrode, where the source electrode and the drain electrode of the sixth transistor T6 may be connected. In an embodiment, the gate of the sixth transistor T6 may be connected to the second transistor T2, and the source electrode and the drain electrode thereof may be connected to the second node N2. In another embodiment, the gate of the sixth transistor T6 may be connected to the second node N2, and the source electrode and the drain electrode thereof may be connected to the second transistor T2. When a turn-on level voltage is applied to the gate of the sixth transistor T6, the source electrode and the drain electrode may be connected to each other through a channel. Accordingly, the gate of the sixth transistor T6 may function as one electrode of a capacitor, and the channel area of the sixth transistor T6 may function as the other electrode of the capacitor.

In an embodiment, the seventh transistor T7 may include a gate, a source electrode, and a drain electrode, where the source electrode and the drain electrode of the seventh transistor T7 may be connected. In an embodiment, the gate of the seventh transistor T7 may be connected to the second node N2, and the source electrode and drain electrode thereof may be connected to a fourth power line PL4. In another embodiment, the gate of the seventh transistor T7 may be connected to the fourth power line PL4, and the source electrode and the drain electrode thereof may be connected to the second node N2. When a turn-on level voltage is applied to the gate of the seventh transistor T7, the source electrode and the drain electrode thereof may be connected to each other through a channel. Accordingly, the gate of the seventh transistor T7 may function as one electrode of a capacitor, and the channel area of the seventh transistor T7 may function as the other electrode of the capacitor.

A constant voltage may be applied to the fourth power line PL4. In an embodiment, the first power voltage ELVDD may be applied to the fourth power line PL4. In an embodiment, a (1-2)-th power voltage ELVDD2 may be applied to the fourth power line PL4. In another embodiment, the (1-1)-th power voltage ELVDD1 may be applied to the fourth power line PL4. In still another embodiment, the initialization voltage VINT may be applied to the fourth power line PL4.

In an embodiment in which the gate of the seventh transistor T7 is applied to the fourth power line PL4, the initialization voltage VINT may be applied to the fourth power line PL4.

As described above, the sub-pixel circuit SPC may include the first to seventh transistors T1 to T7, respectively. However, invention is not limited thereto. The sub-pixel circuit SPC may be implemented as one of various types of circuits including a plurality of transistors. Depending on the embodiment of the sub-pixel circuit SPC, the number of sub-gate lines included in the i-th gate line GLi′ may vary. In some embodiments, the i-th light emitting control line ELi may include a sub-light emitting control line. In the above embodiment, the number of sub-light emitting control lines included in the i-th light emitting control line ELi may be two or more.

In an embodiment, the transistors T1 to T7 may be P-type transistors, where the P-type transistor may be turned on in response to a low-level signal and may be turned off in response to a high-level signal. Each of the transistors T1 to T7 may be a metal oxide silicon field effect transistor (MOSFET). However, the invention is not limited thereto. For example, in another embodiment, at least one of the transistors T1 to T7 may be replaced with an N-type transistor. The N-type transistor may be turned on in response to a high-level signal and may be turned off in response to a low-level signal.

In an embodiment, the transistors T1 to T7 may include an amorphous silicon semiconductor, a monocrystalline silicon semiconductor, a polycrystalline silicon semiconductor, a metal oxide semiconductor, and the like.

In an embodiment, the light emitting element LD may include a first electrode, a second electrode, and a light emitting layer. The first electrode may be the anode electrode AE, and the second electrode may be the cathode electrode CE. The light emitting layer may be disposed between the anode electrode AE and the cathode electrode CE. After the data signal transmitted through the j-th data line DLj is reflected in the voltage of the second node N2, the fourth transistor T4 may be turned on when the light emitting control signal EM[i] of the i-th light emitting control line ELi is enabled to a low level. In addition, the first transistor T1 may be turned on according to the voltage of the second node N2, and thus a current may flow from the first power line PL1 to the second power line PL2. The light emitting element LD may emit light according to an amount of flowing current (for example, driving current).

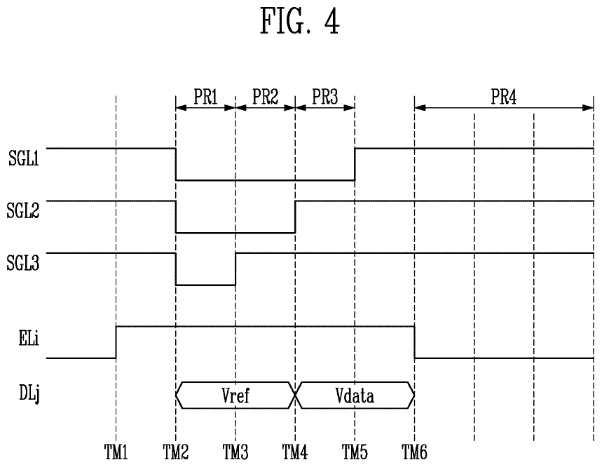

FIG. 4 illustrates an example of a driving timing diagram of a sub-pixel, according to an embodiment.

In an embodiment and referring to FIG. 4, first to sixth time points (or first to sixth timings) TM1 to TM6, respectively, and first to fourth periods PRI to PR4, respectively, are shown. The timing diagram shown in FIG. 4 may illustrate the timing of the signal supplied to the sub-pixel SPij of FIG. 3.

It should be appreciated that the description will be made assuming that the high-level voltage applied to the sub-gate lines SGL1 to SGL3 and the i-th light emitting control line ELi is a turn-off level voltage, and the low-level voltage applied thereto is a turn-on level voltage.

In an embodiment, at the first time point TM1, a high-level voltage may be applied to the first sub-gate line SGL1, a high-level voltage may be applied to the second sub-gate line SGL2, and a high-level voltage may be applied to the third sub-gate line SGL3. The i-th light emitting control line ELi may transition from a low-level voltage to a high-level voltage.

In an embodiment, at the second time point TM2, the first sub-gate line SGL1 may transition from a high-level voltage to a low-level voltage, the second sub-gate line SGL2 may transition from a high-level voltage to a low-level voltage, and the third sub-gate line SGL3 may transition from a high-level voltage to a low-level voltage. A high-level voltage may be applied to the i-th light emitting control line ELi.

In an embodiment, at the third time point TM3, a low-level voltage may be applied to the first sub-gate line SGL1, and a low-level voltage may be applied to the second sub-gate line SGL2. The third sub-gate line SGL3 may transition from a low-level voltage to a high-level voltage. A high-level voltage may be applied to the i-th light emitting control line ELi.

In an embodiment, at the fourth time point TM4, a low-level voltage may be applied to the first sub-gate line SGL1, and a high-level voltage may be applied to the third sub-gate line SGL3. The second sub-gate line SGL2 may transition from a low-level voltage to a high-level voltage. A high-level voltage may be applied to the i-th light emitting control line ELi.

In an embodiment, at the fifth time point TM5, the first sub-gate line SGL1 may transition from a low-level voltage to a high-level voltage. A high-level voltage may be applied to the second sub-gate line SGL2, and a high-level voltage may be applied to the third sub-gate line SGL3. A high-level voltage may be applied to the i-th light emitting control line ELi.

In an embodiment, at the sixth time point TM6, a high-level voltage may be applied to the first sub-gate line SGL1, a high-level voltage may be applied to the second sub-gate line SGL2, and a high-level voltage may be applied to the third sub-gate line SGL3. The i-th light emitting control line ELi may transition from a high-level voltage to a low-level voltage.

The period between the second time point TM2 and the third time point TM3 is the first period PR1, and this period may correspond to the initialization period.

The period between the third time point TM3 and the fourth time point TM4 is the second period PR2, and this period may correspond to the compensation period.

The period between the fourth time point TM4 and the fifth time point TM5 is the third period PR3, and this period may correspond to the data write period.

A period (for example, a predetermined period) after the sixth time point TM6 is the fourth period PR4, and this period may correspond to the light emitting period.

In an embodiment, a reference voltage Vref may be applied to the j-th data line DLj during the first period PRI and the second period PR2. A data signal Vdata may be applied to the j-th data line DLj during the third period PR3. The voltage applied to the data line DLj during the remaining period is omitted, for better understanding and ease of description.

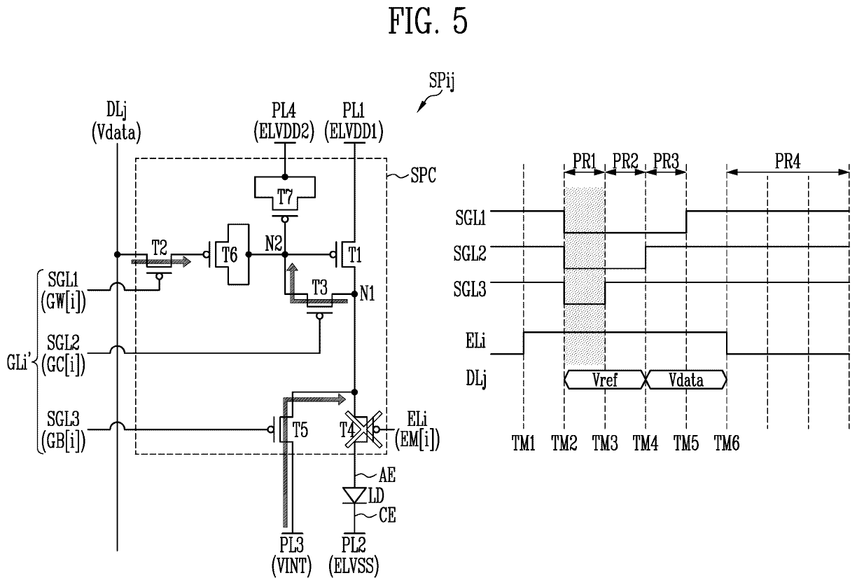

FIG. 5 to FIG. 8 are drawings for specifically describing the equivalent circuit diagram of FIG. 3 and the driving timing diagram of FIG. 4, according to an embodiment.

In an embodiment and referring to FIG. 5, during the first period PRI, the second transistor T2, the third transistor T3, and the fifth transistor T5 may be in a turn-on state. The fourth transistor T4 may be in a turn-off state.

The reference voltage Vref is applied to the j-th data line DLj. The j-th data line DLj and the gate of the sixth transistor T6 may be electrically connected through the second transistor T2. The gate of the sixth transistor T6 may be initialized to the reference voltage Vref. The reference voltage Vref may be a voltage at the turn-on level of the sixth transistor T6.

When the fifth transistor T5 is turned on, the first node N1 may be electrically connected to the third power line PL3. The initialization voltage VINT may be applied to the first node N1. When the third transistor T3 is turned on, the second node N2 may be initialized to the initialization voltage VINT. The initialization voltage VINT may be a voltage at the turn-on level of the seventh transistor T7. The initialization voltage VINT may be an initialization voltage of the first transistor T1.

In an embodiment, as the sixth transistor T6 and the seventh transistor T7 are turned on, each of the sixth transistor T6 and the seventh transistor T7 may function as a capacitor.

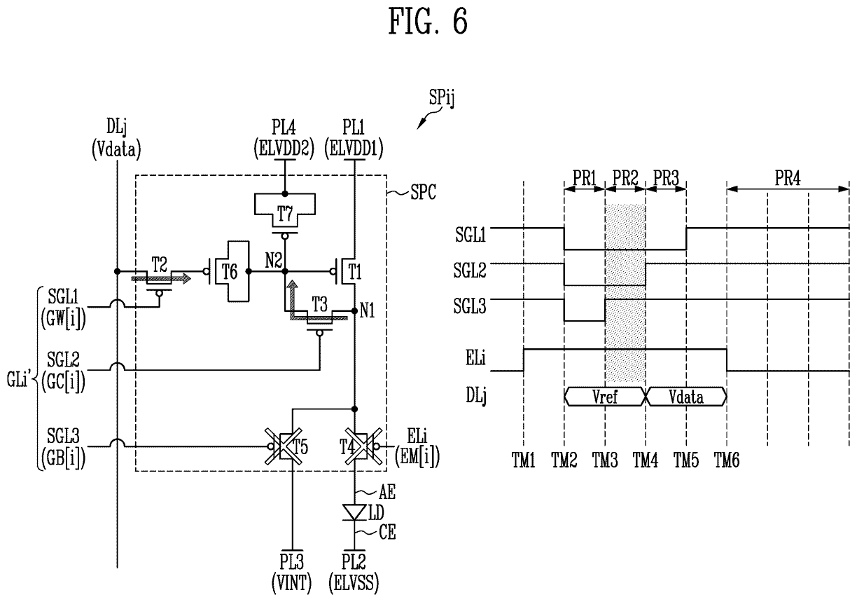

In an embodiment and referring to FIG. 6, during the second period PR2, the second transistor T2 and the third transistor T3 may be in a turn-on state and the fourth transistor T4 and the fifth transistor T5 may be in a turn-off state.

In the state in which the fourth transistor T4 and the fifth transistor T5 are turned off, the first transistor T1 may be diode-connected. The voltage of the second node N2 may vary from the initialization voltage VINT as shown in Equation 1 immediately below:

$$V ( N 2 ) = EL V DD 1 + V th of T 1 , \qquad ( Equation 1 )$$

where, in Equation 1, V(N2) indicates a voltage of the second node N2, ELVDD1 indicates a level of a voltage applied to the first power line PL1 And Vth of T1 indicates a threshold voltage of the first transistor T1.

In an embodiment, a voltage reflecting the threshold voltage of the first transistor T1 may be stored in the second node N2, where the magnitude of the voltage applied to the second node N2 during the second period PR2 may be the turn-on level voltage of the seventh transistor T7.

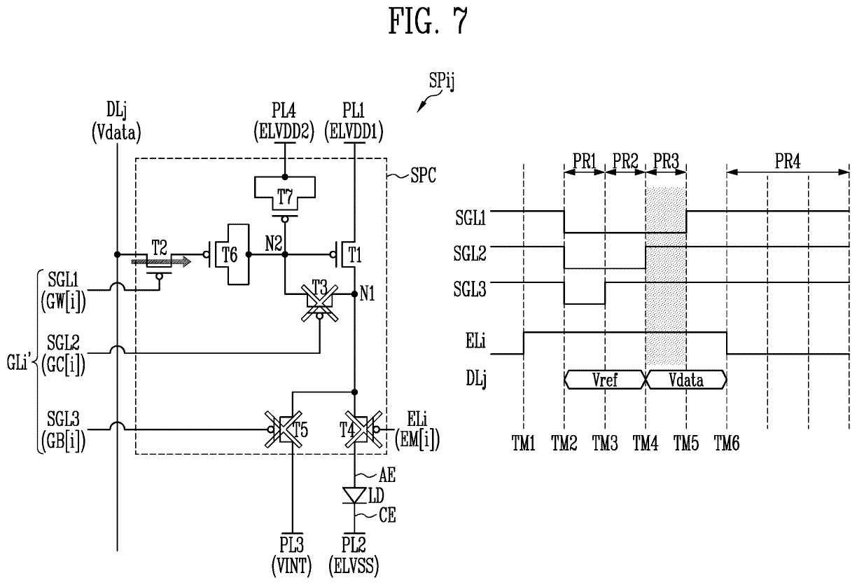

In an embodiment and referring to FIG. 7, the second transistor T2 may be in a turn-on state and the third transistor T3, the fourth transistor T4, and the fifth transistor T5 may be in a turn-off state.

The gate of the sixth transistor T6 may be connected to the j-th data line DLj via the second transistor T2, so that the data signal Vdata may be applied. The data signal Vdata may be the turn-on level voltage of the sixth transistor T6.

As the voltage applied to the gate of the sixth transistor T6 varies from the reference voltage Vref to the data signal Vdata corresponding to the grayscale value, the voltage of the second node N2 may also vary. The voltage of the second node N2 may vary based on a ratio between the capacitance formed by the sixth transistor T6 and the capacitance formed by the seventh transistor T7. The voltage of the second node N2 may vary as shown in Equation 2 immediately below:

$$V ( N 2 ) = ( EL V DD 1 + V th of T 1 ) + \frac{( V ref - V data ) TC 1}{( TC 1 + TC 2 )} , \qquad ( Equation 2 )$$

where, in Equation 2, V(N2) indicates a voltage of the second node N2, (ELVDD1+Vth of T1) indicates a voltage of the second node N2 during the second period PR2, TC1 is a capacitance of the sixth transistor T6, and represents a magnitude of a capacitance formed by the gate and the channel area of the sixth transistor T6, TC2 is a capacitance of the seventh transistor T7, and represents a magnitude of a capacitance formed by the gate and the channel area of the seventh transistor T7, Vref represents a level of a reference voltage applied to the j-th data line DLj during the second period PR2 and Vdata represents a level of a data signal applied to the j-th data line DLj during the third period PR3. During the third period PR3, the voltage of the second node N2 may be the turn-on level voltage of the seventh transistor T7.

In an embodiment, a voltage capable of compensating for the change amount of the threshold voltage of the first transistor T1 may be stored in the second node N2.

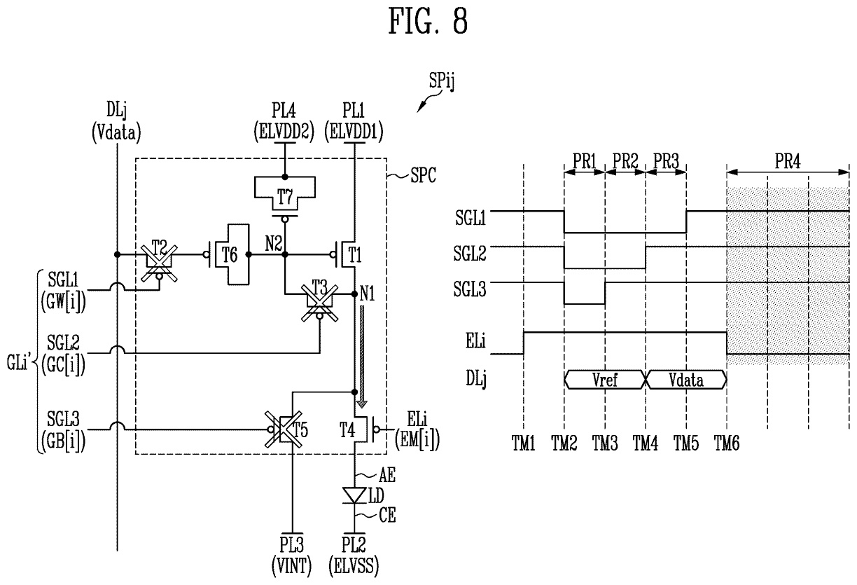

In an embodiment and referring to FIG. 8, during the fourth period PR4, the second transistor T2, the third transistor T3, and the fifth transistor T5 may be in a turn-off state and the fourth transistor T4 may be in a turn-on state.

The amount of the driving current flowing through the first transistor T1 during the fourth period PR4 in the saturation region is expressed in Equation 3 immediately below:

$${I}_{D} = μ \times Cox \times \frac{W}{L} \times {( EL V DD + \frac{( V ref - V data ) \times TC 1}{TC 1 + TC 2} )}^{2} , \qquad ( Equation 3 )$$

where, in Equation 3, I_{D} represents an amount of the drain current or the driving current flowing through the first transistor T1, μ represents a mobility of the first transistor T1, Cₒₓ represents a gate capacitance per unit area of the first transistor T1, L represents a length of the channel of the first transistor T1 and W represents a width of the channel of the first transistor T1. The remaining symbols are as described through Equation 2.

Accordingly, in an embodiment, the change in threshold voltage of the first transistor T1 may be compensated for and the driving current may be supplied, during the fourth period PR4.

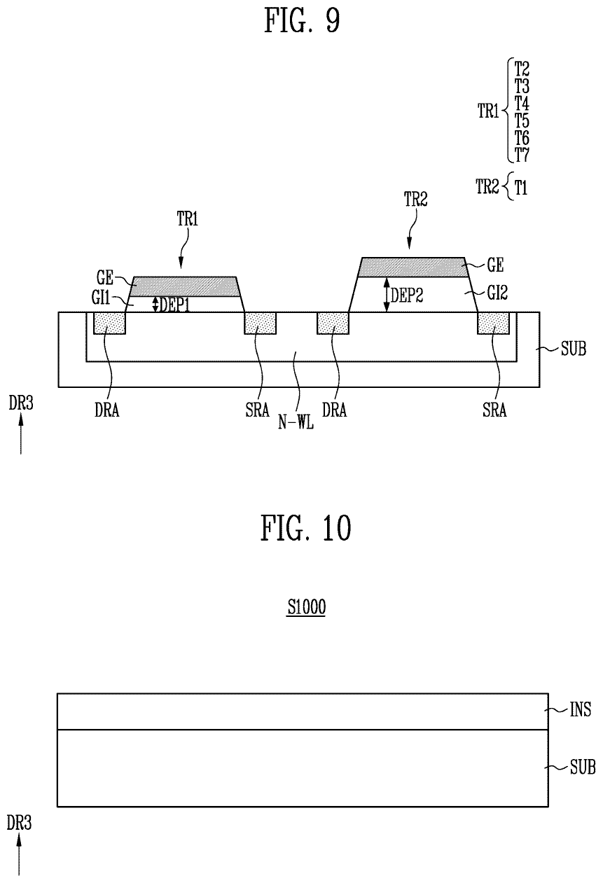

FIG. 9 schematically illustrates a semiconductor layer and a gate of each of a first type transistor TR1 and a second type transistor TR2 according to the embodiment of FIG. 3, according to an embodiment.

Referring to FIG. 9, an embodiment is shown in which the semiconductor layers of the first type transistor TR1 and the second type transistor TR2 are directly formed on a substrate SUB, respectively.

In an embodiment, each of the first type transistor TR1 and the second type transistor TR2 may include a source area SRA, a drain area DRA, and a gate electrode GE.

The source area SRA and the drain area DRA may be disposed within the substrate SUB. A well formed through an ion implantation process may be disposed within the substrate SUB. In an embodiment, the well may be configured as an N-well N-WL. However, the invention is not limited thereto.

In an embodiment, the source area SRA and the drain area DRA may be disposed to be spaced apart from each other within the well. For example, the area between the source area SRA and the drain area DRA within the well N-WL may be defined as a channel area.

In an embodiment, the gate electrode GE may overlap the channel area disposed between the source area SRA and the drain area DRA, where the gate electrode GE may be spaced apart from the well or channel area by a gate insulating layer including an insulating material. The gate electrode GE may include a conductive material.

The gate electrode GE of the first type transistor TR1 may be disposed on a first gate insulating layer GI1 and the gate electrode GE of the second type transistor TR2 may be disposed on a second gate insulating layer GI2.

In an embodiment, the first gate insulating layer GI1 may have a first thickness DEP1 and the second gate insulating layer GI2 may have a second thickness DEP2. The second thickness DEP2 may be larger than the first thickness DEP1.

In an embodiment, the transistors T2 to T7 may be implemented as the first type transistor TR1. Accordingly, a sub-pixel circuit SPC as proposed in FIG. 3 may be implemented without forming a separate capacitor on the transistor. Thereby, forming the sub-pixel circuit SPC may be simplified.

In an embodiment, the first transistor T1 may be implemented as the second type transistor TR2. By increasing the second thickness DEP2, the value of the gate capacitance Cₒₓ per unit area of the first transistor T1 described through Equation 3 may increase. Accordingly, the channel length L of the first transistor T1 may be relatively shortened. By shortening the channel length of the first transistor T1, the degree of integration of the transistors T1 to T7 may be increased. Accordingly, a small display device 100 (see FIG. 1) may be provided by integrating transistors at a high density within the same area without forming a separate capacitor on the transistor.

FIG. 10 to FIG. 20 specifically illustrate steps of forming the gate of each of the first and second type transistors TR1 and TR2, respectively, of FIG. 9.

In an embodiment and referring to FIG. 10, in step S1000 of forming an insulating layer INS, the insulating layer INS including an insulating material may be formed on the substrate SUB.

In an embodiment, the substrate SUB may be a silicon substrate, but is not limited thereto.

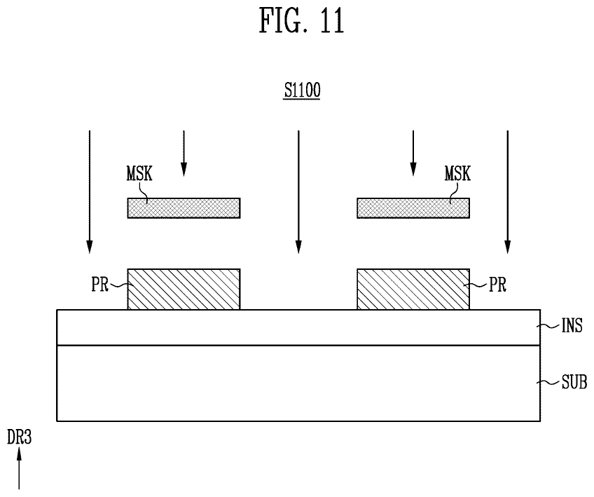

In an embodiment and referring to FIG. 11, in step S1100 of primarily patterning a photoresist PR, the photoresist PR may be patterned using a mask MSK. The photoresist PR may be disposed on the insulating layer INS. The photoresist PR may be implemented as one of a positive photoresist and a negative photoresist. In an embodiment, when light is irradiated to the photoresist PR through an open area of the mask MSK, the photoresist PR may be removed from the light-irradiated area so that the photoresist PR may be patterned.

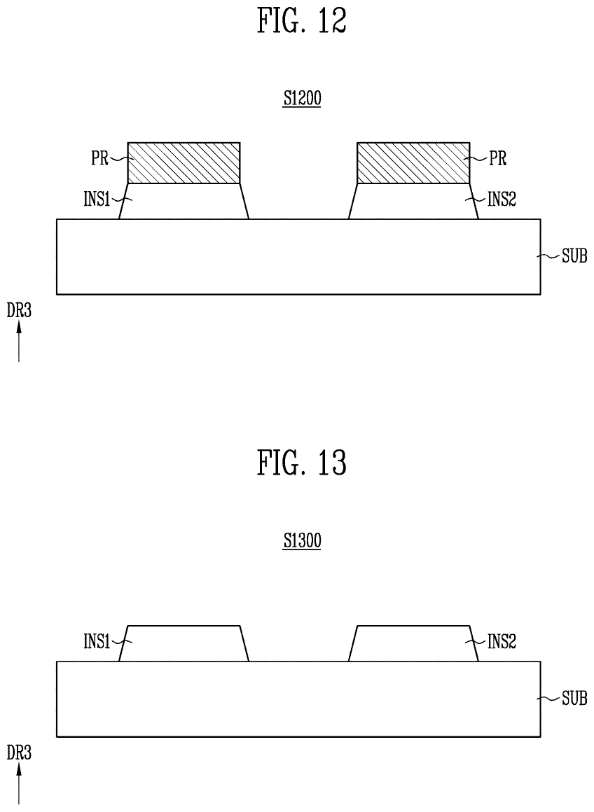

In an embodiment and referring to FIG. 12, in step S1200 of primarily removing the insulating layer, the insulating layer INS may be removed (for example, etched) according to the pattern of the patterned photoresist PR.

In an embodiment and referring to FIG. 13, in step S1300 of removing the photoresist, the patterned photoresist PR of FIG. 12 may be removed. Accordingly, a first insulating layer INS1 and a second insulating layer INS2 may be formed.

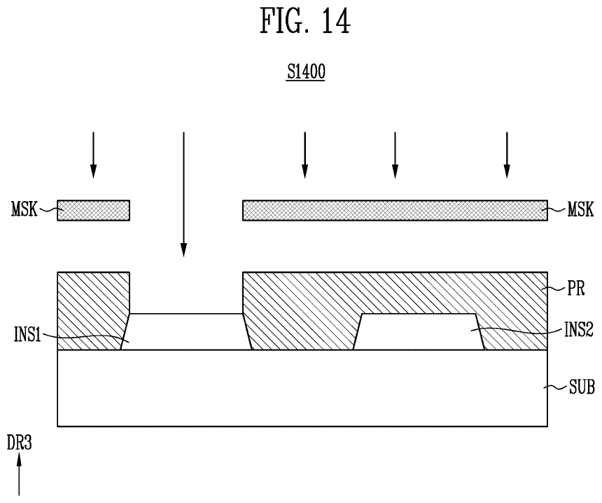

In an embodiment and referring to FIG. 14, in step S1400 of secondarily patterning the photoresist, the photoresist PR may be patterned using a mask MSK. In an embodiment, the patterned photoresist PR may expose an upper surface of the first insulating layer INS1.

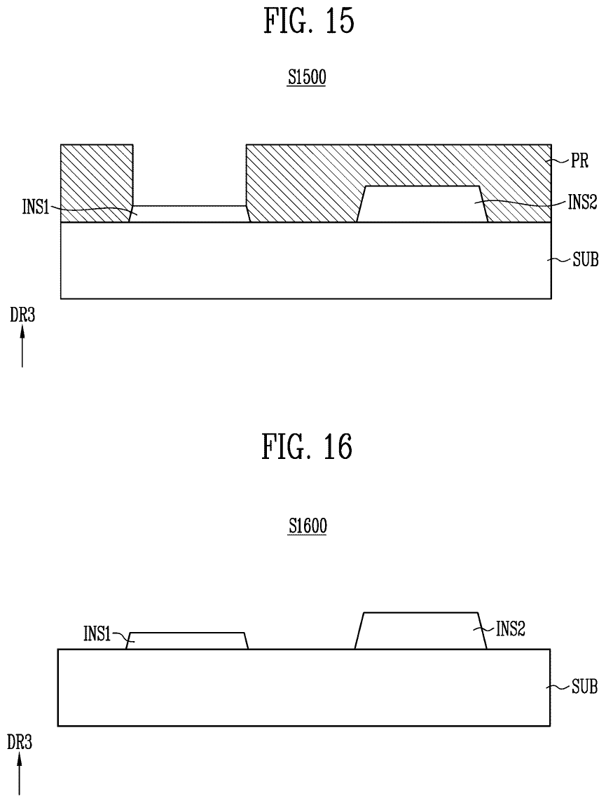

In an embodiment and referring to FIG. 15, in step S1500 of secondarily removing the insulating layer, at least a portion of the first insulating layer INS1 may be removed (for example, etched) according to the pattern of the patterned photoresist PR.

In an embodiment and referring to FIG. 16, in step S1600 of removing the photoresist, the patterned photoresist PR of FIG. 15 may be removed. Accordingly, the first insulating layer INS1 and the second insulating layer INS2 having different thicknesses may be exposed.

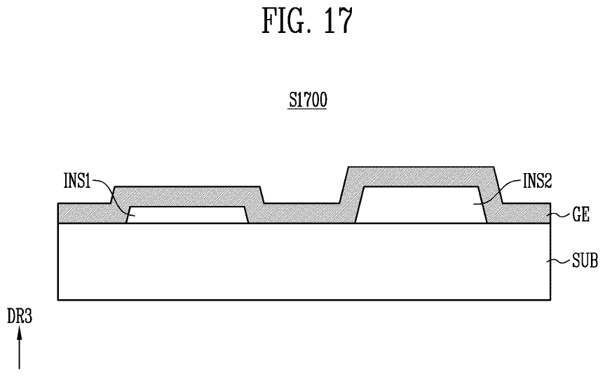

In an embodiment and referring to FIG. 17, in step S1700 of forming the gate electrode GE, a conductive material configuring the gate electrode GE may be disposed on the first insulating layer INS1 and the second insulating layer INS2.

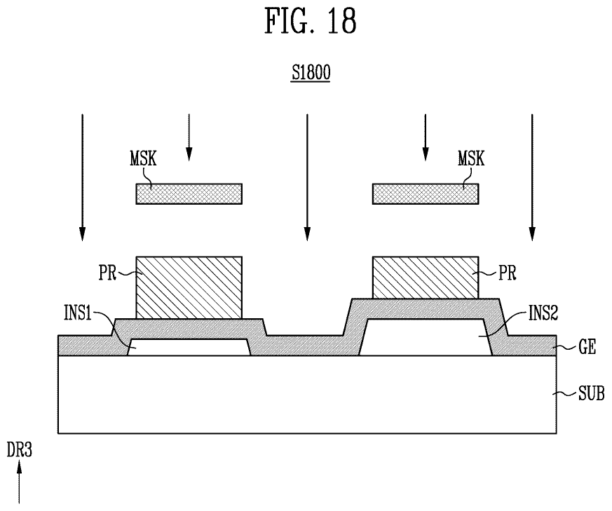

In an embodiment and referring to FIG. 18, in step S1800 of thirdly patterning the photoresist, the photoresist PR may be patterned using a mask MSK. In an embodiment, the patterned photoresist PR may remain on the first insulating layer INS1 and the second insulating layer INS2.

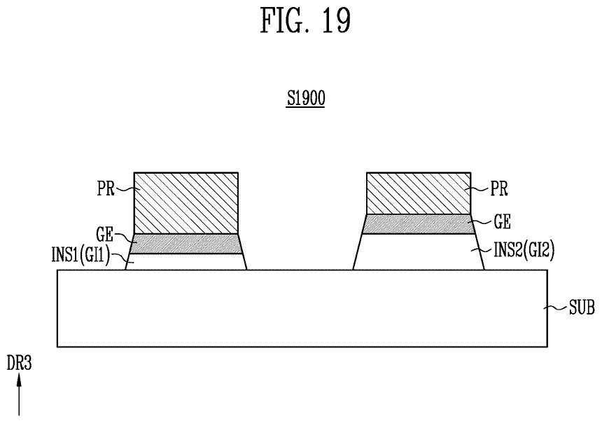

In an embodiment and referring to FIG. 19, in step S1900 of removing the gate electrode GE, at least a portion of the conductive material configuring the gate electrode GE may be removed according to the pattern of the patterned photoresist PR. Accordingly, side surfaces of the first and second insulating layers INS1 and INS2 may be exposed

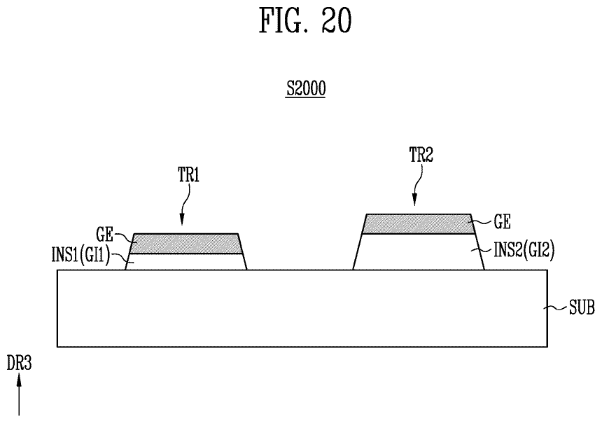

In an embodiment and referring to FIG. 20, in step S2000 of removing the photoresist, the gate electrode GE of the first type transistor TR1 and the gate electrode GE of the second type transistor TR2 may be exposed. The first insulating layer INS1 may function as the first gate insulating layer GI1 of the first type transistor TR1. The second insulating layer INS2 may function as the second gate insulating layer GI2 of the second type transistor TR2.

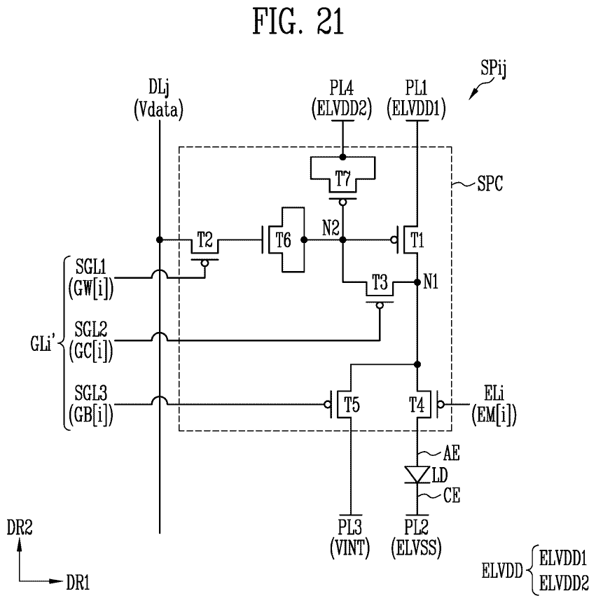

FIG. 21 illustrates an equivalent circuit diagram of the sub-pixel SPij of FIG. 2, according to another embodiment.

Comparing the equivalent circuit diagram in FIG. 21 with the equivalent circuit diagram in FIG. 3, there is a difference in the configuration of the sixth transistor T6, and the remaining configurations are the same as a whole.

In an embodiment, the sixth transistor T6 may include a gate connected to the second transistor T2, where the sixth transistor T6 may include a source electrode and a drain electrode connected to the second node N2. In the above embodiment, the data signal Vdata applied to the j-th data line DLj may have a higher voltage level than the data signal Vdata applied to the j-th data line DLj to display an image of the same grayscale in the embodiment of FIG. 3.

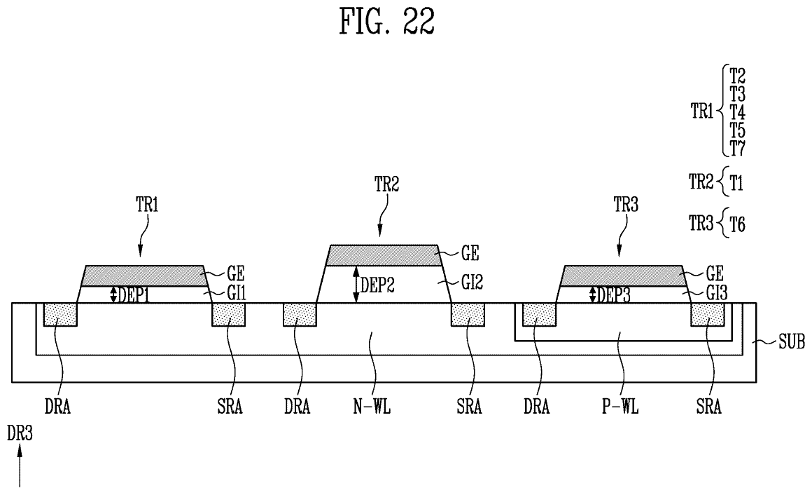

FIG. 22 schematically illustrates a semiconductor layer and a gate of each of the first type transistor TR1, the second type transistor TR2, and the third type transistor TR3, according to the embodiment of FIG. 21.

In an embodiment, the first type transistor TR1, the second type transistor TR2, and the third type transistor TR3 may be disposed on the substrate SUB.

The first type transistor TR1 and the second type transistor TR2 may be configured as transistors including a P type semiconductor layer and the third type transistor TR3 may be configured as a transistor including an N type semiconductor layer.

The source areas SRA and the drain areas DRA of the first type transistor TR1 and the second type transistor TR2 may be disposed to be spaced apart from each other within the N-well N-WL.

The source area SRA and the drain area DRA of the third type transistor TR3 may be disposed to be spaced apart from each other within the P-well P-WL.

In an embodiment, within the substrate SUB, the N-well N-WL may be deeper than the P-well P-WL. For example, the N-well N-WL may be formed before the P-well P-WL.

The first type transistor TR1 may include the first gate insulating layer GI1. The second type transistor TR2 may include the second gate insulating layer GI2. The third type transistor TR3 may include the third gate insulating layer GI3.

In an embodiment, the first thickness DEP1 of the first gate insulating layer GI1 may be the same as (or substantially the same) the third thickness DEP3 of the third gate insulating layer GI3. In an embodiment, the second thickness DEP2 of the second gate insulating layer GI2 may be greater than the third thickness DEP3 of the third gate insulating layer GI3.

The transistors T2, T3, T4, T5, and T7 may be implemented as the first type transistor TR1. The first transistor T1 may be implemented as the second type transistor TR2 and the sixth transistor T6 may be implemented as the third type transistor TR3.

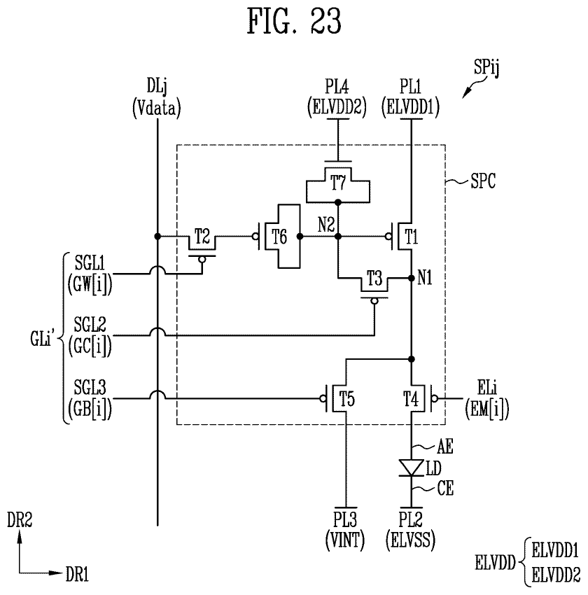

FIG. 23 illustrates an equivalent circuit diagram of the sub-pixel SPij of FIG. 2, according to another embodiment.

Comparing the equivalent circuit diagram in FIG. 23 with the equivalent circuit diagram in FIG. 3, there is a difference in the configuration of the seventh transistor T7, and the remaining configurations are the same as a whole.

The seventh transistor T7 may include a gate connected to the fourth power line PL4. The seventh transistor T7 may include a source electrode and a drain electrode connected to the second node N2. In the above embodiment, the voltage applied to the fourth power line PL4 may be a turn-on level voltage of the seventh transistor T7.

In an embodiment, when the seventh transistor T7 is implemented as a transistor including an N-type semiconductor layer, a high-level voltage for turning on the seventh transistor T7 may be applied to the fourth power line PL4. In an embodiment, the high-level voltage may be, for example, the (1-2)-th power voltage ELVDD2.

In another embodiment, when the seventh transistor T7 is implemented as a transistor including a P-type semiconductor layer, a low-level voltage for turning on the seventh transistor T7 may be applied to the fourth power line PL4, where the low-level voltage may be, for example, the initialization voltage VINT.

The equivalent circuit diagram of FIG. 23 illustrates an embodiment in which the seventh transistor T7 is implemented as a transistor including an N-type semiconductor layer as an example, but the invention not limited thereto.

Accordingly, the seventh transistor T7 maintains the turn-on state, so that the seventh transistor T7 may function similarly to a capacitor.

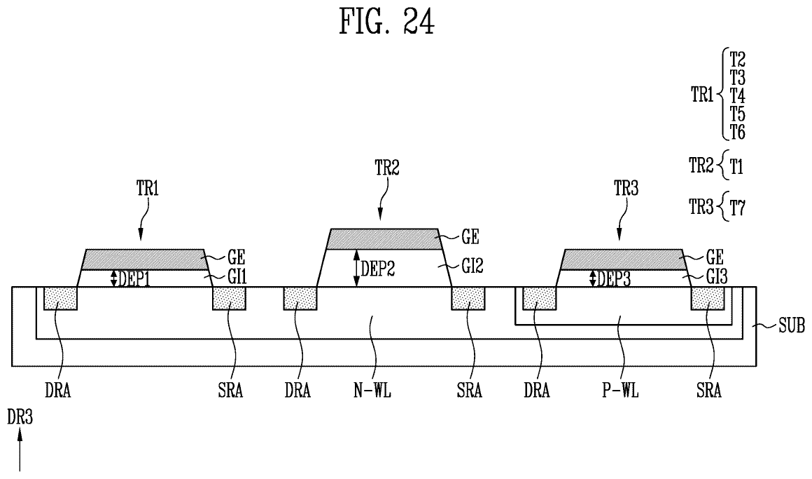

FIG. 24 schematically illustrates a semiconductor layer and a gate of each of the first type transistor TR1, the second type transistor TR2, and the third type transistor TR3, according to the embodiment of FIG. 23.

Comparing the drawing of FIG. 24 with the drawing of FIG. 22, there is a difference only between the transistor implemented as the first type transistor TR1 and the transistor implemented as the third type transistor TR3.

In an embodiment, the transistors T2 to T6 may be implemented as the first type transistor TR1. The first transistor T1 may be implemented as the second type transistor TR2. The seventh transistor T7 may be implemented as the third type transistor TR3.

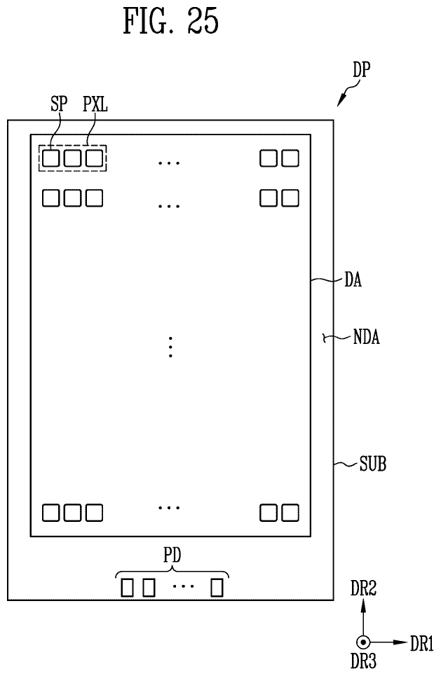

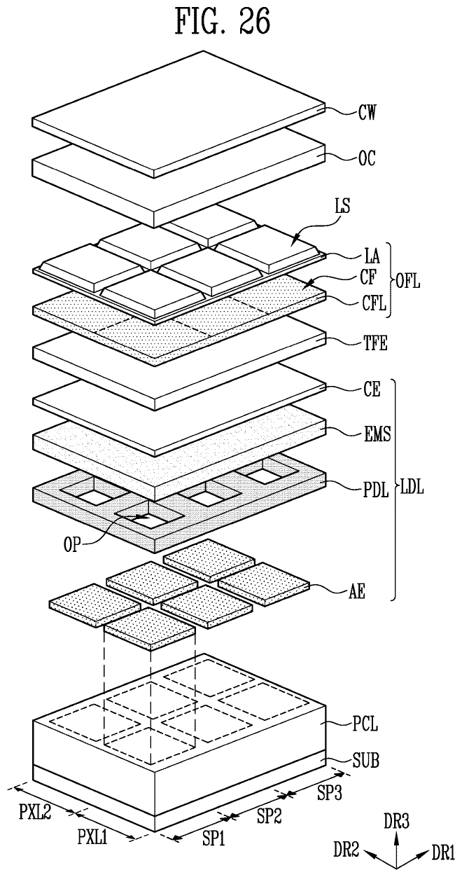

FIG. 25 illustrates a top plan view of the display panel 110 of FIG. 1, according to an embodiment.

Referring to FIG. 25, an embodiment DP of the display panel 110 of FIG. 1 may include a display area DA and a non-display area NDA, where the display panel DP displays an image through the display area DA and where the non-display area NDA is disposed around the display area DA.

The display panel DP may include a substrate SUB, sub-pixels SP, and pads PD.

When the display panel DP is used as a display screen for a head-mounted display (HMD), a virtual reality (VR) device, a mixed reality (MR) device, and an augmented reality (AR) device, the display panel DP may be positioned very close to the user's eyes. In this case, the sub-pixels SP with relatively high integration are required. In order to increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLED on silicon (OLEDoS) display device.

In an embodiment, the sub-pixels SP are disposed in the display area DA on the substrate SUB. The sub-pixels SP may be arranged in a matrix format along a first direction DR1 and a second direction DR2 that intersects the first direction DR1. However, the invention is not limited thereto. For example, in an embodiment, the sub-pixels SP may be arranged in a zigzag form along first direction DR1 and second direction DR2. For example, the sub-pixels SP may be disposed in a PENTILE™ shape. The first direction DR1 may be a row direction, and the second direction DR2 may be a column direction.

In an embodiment, two or more of the plurality of sub-pixels SP may configure one pixel PXL.

A constituent element to control the sub-pixels SP may be disposed in the non-display area NDA on the substrate SUB. For example, wires connected to the sub-pixels SP, such as the gate lines GL1 to GLm and the data lines DL1 to DLn of FIG. 1, may be disposed in the non-display area NDA.

In an embodiment, an alignment mark may be disposed in the non-display area NDA. The alignment mark may be configured to align the display panel DP.

At least one of the gate driver 120, the data driver 130, the voltage generator 140, the controller 150, and the temperature sensor 160 in FIG. 1 may be integrated in the non-display area NDA of the display panel DP. In an embodiment, the gate driver 120 of FIG. 1 may be mounted on the display panel DP and may be disposed in the non-display area NDA. In an embodiment, the gate driver 120 may be implemented as an integrated circuit separated from the display panel DP. In an embodiment, the temperature sensor 160 may be disposed in the non-display area NDA to detect the temperature of the display panel DP.

In an embodiment, the pads PD are disposed in the non-display area NDA on the substrate SUB and may be electrically connected to the sub-pixels SP through wires. For example, the pads PD may be connected to the sub-pixels SP through the data lines DL1 to DLn.

The pads PD may interface the display panel DP to other constituent elements of the display device 100 (see FIG. 1). In an embodiment, voltages and signals required for operations of constituent elements included in the display panel DP may be provided from the driver integrated circuit DIC of FIG. 1 through the pads PD. For example, the data lines DL1 to DLn may be connected to the driver integrated circuit DIC through the pads PD. For example, the first and second power voltages VDD and VSS, respectively, may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In an embodiment, the circuit board may be electrically connected to the pads PD by using a conductive adhesive member such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

In an embodiment, the display area DA may have various shapes. The display area DA may have a closed-loop shape including sides of a straight line and/or a curved line. For example, the display area DA may have shapes such as a polygonal shape, a circular shape, a semicircular, and an elliptical shape.

In an embodiment, the display panel DP may have a flat display surface. In other embodiments, the display panel DP may have a display surface that is at least partially round. In an embodiment, the display panel DP may be bendable, foldable, or rollable. In these embodiments, the display panel DP and/or the substrate SUB may include materials with flexible properties.

FIG. 26 illustrates an exploded perspective view of a portion of the display panel DP of FIG. 25, according to an embodiment.

In FIG. 26, for clear and concise description, a portion of the display panel DP corresponding to two pixels PXL1 and PXL2 among the pixels PXL of FIG. 25 is schematically shown. Portions of the display panel DP corresponding to the remaining pixels may be similarly configured.

In an embodiment and referring to FIG. 25 and FIG. 26, each of the pixels PXL1 and PXL2 may include sub-pixels SP1 to SP3. However, the invention is not limited thereto. For example, each of the pixels PXL1 and PXL2 may include four sub-pixels, or two sub-pixels.

In FIG. 26, the sub-pixels SP1 to SP3 are illustrated to have quadrangular shapes and have the same sizes when viewed in the third direction DR3 crossing the directions DR1 and DR2. However, the invention is not limited thereto and the sub-pixels SP1 to SP3 may be modified to have various shapes.

In an embodiment, the display panel DP may include a substrate SUB, a pixel circuit layer PCL, a light emitting element layer LDL, an encapsulation layer TFE, an optical functional layer OFL, an overcoat layer OC, and a cover window CW.

In an embodiment, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOI) layer. In another embodiment, the substrate SUB may include a glass substrate. In still another embodiment, the substrate SUB may include a polyimide (PI) substrate.

In an embodiment, the pixel circuit layer PCL is disposed on the substrate SUB, where the substrate SUB and/or the pixel circuit layer PCL may include insulating layers and conductive patterns disposed between the insulating layers. The conductive patterns of the pixel circuit layer PCL may function as at least some of circuit elements, wires, and the like

In an embodiment, the conductive patterns may include copper, but the invention is not limited thereto.

In an embodiment, the circuit elements may include the sub-pixel circuit SPC (see FIG. 2) of each of the sub-pixels SP1 to SP3, where the sub-pixel circuit SPC may include transistors. Each transistor may include a semiconductor portion including a source area, a drain area, and a channel area, and a gate electrode overlapping the semiconductor portion. In an embodiment, when the substrate SUB is provided as a silicon substrate, the semiconductor portion may be included in the substrate SUB, and the gate electrode may be included in the pixel circuit layer PCL as the conductive pattern of the pixel circuit layer PCL. In an embodiment, when the substrate SUB is provided as a glass substrate or a PI substrate, the semiconductor portion and the gate electrode may be included in the pixel circuit layer PCL.

In an embodiment, the wires of the pixel circuit layer PCL may include signal lines connected to each of the sub-pixels SP1 to SP3, for example, a gate line, a light emitting control line, and a data line. The wires may further include the wire connected to the first power voltage node VDDN of FIG. 2. In addition, the wires may further include the wire connected to the second power voltage node VSSN of FIG. 2.

In an embodiment, the light emitting element layer LDL may include anode electrodes AE, a pixel defining film PDL, a light emitting structure EMS, and a cathode electrode CE.

The anode electrodes AE may be disposed on the pixel circuit layer PCL and may contact circuit elements of the pixel circuit layer PCL. The anode electrodes AE may include an opaque conductive material capable of reflecting light, but the invention is not limited thereto.

The pixel defining film PDL is disposed on the anode electrodes AE and may include an opening OP exposing a portion of each of the anode electrodes AE. The opening OP of the pixel defining film PDL may be understood as light emitting areas corresponding to the first to third sub-pixels SP1 to SP3, respectively.

In an embodiment, the pixel defining film PDL may include an inorganic material. In this case, the pixel defining film PDL may include a plurality of stacked inorganic layers. For example, the pixel defining film PDL may include a silicon oxide (SiOₓ) and a silicon nitride (SiNₓ). In another embodiment, the pixel defining film PDL may include an organic material. However, the material of the pixel defining film PDL is not limited thereto.

The light emitting structure EMS may be disposed on the anode electrodes AE exposed by the opening OP of the pixel defining film PDL. The light emitting structure EMS may include a light emitting layer configured to generate light, an electron transport layer configured to transport electrons, and a hole transport layer configured to transport holes.

In an embodiment, the light emitting structure EMS may fill the opening OP of the pixel defining film PDL, and may be disposed entirely on an upper portion of the pixel defining film PDL. In other words, the light emitting structure EMS may extend across the sub-pixels SP1 to SP3. In this case, at least some of the functional layers in the light emitting structure EMS may be disconnected or bent at the boundaries between the sub-pixels SP1 to SP3. However, the invention is not limited thereto. For example, portions of the light emitting structure EMS corresponding to the sub-pixels SP1 to SP3 are separated from each other, and each of them may be disposed in the opening OP of the pixel defining film PDL.

The cathode electrode CE may be disposed on the light emitting structure EMS. The cathode electrode CE may extend across the sub-pixels SP1 to SP3. As such, the cathode electrode CE may be provided as a common electrode for the sub-pixels SP1 to SP3.

The cathode electrode CE may be a thin metal layer with a thickness sufficient to transmit light emitted from the light emitting structure EMS. The cathode electrode CE may be made of a metallic material or a transparent conductive material to have a relatively thin thickness. In an embodiment, the cathode electrode CE may include at least one of various transparent conductive materials including an indium tin oxide, an indium zinc oxide, an indium tin zinc oxide, an aluminum zinc oxide, a gallium zinc oxide, a zinc tin oxide, and a gallium tin oxide. In another embodiment, the cathode electrode CE may include at least one of silver (Ag), magnesium (Mg), and a mixture thereof. However, the material of the cathode electrode CE is not limited thereto.

One of the anode electrodes AE, the portion of the light emitting structure EMS overlapping it, and the portion of the cathode electrode CE overlapping it may be understood to configure one light emitting element LD (see FIG. 2). In other words, each of the light emitting elements of the sub-pixels SP1 to SP3 may include one anode electrode, a portion of the light emitting structure EMS overlapping it, and a portion of the cathode electrode CE overlapping it. In each of the sub-pixels SP1 to SP3, holes injected from the anode electrode AE and electrons injected from the cathode electrode CE are transported into the light emitting layer of the light emitting structure EMS to form excitons, and when the excitons transition from the excited state to the ground state, light may be generated. The luminance of light may be determined depending on the amount of current flowing through the light emitting layer. Depending on the configuration of the light emitting layer, the wavelength range of the generated light may be determined.

In an embodiment, the encapsulation layer TFE is disposed on the cathode electrode CE and may cover the light emitting element layer LDL and/or the pixel circuit layer PCL. The encapsulation layer TFE may be configured to prevent oxygen and/or moisture from penetrating into the light emitting element layer LDL. In an embodiment, the encapsulation layer TFE may include a structure in which one or more inorganic films and one or more organic films are alternately stacked. For example, the inorganic film may include a silicon nitride, a silicon oxide, or a silicon oxynitride (SiOₓN_{y}). For example, the organic film may include an organic insulating material such as an acrylic resin, an epoxy resin, a phenol resin, a polyamide resin, a polyimide resin, an unsaturated polyesters resin, a polyphenylene ethers resin, a polyphenylenesulfides resin, or a benzocyclobutene (BCB). However, the materials of the organic film and the inorganic film of the encapsulation layer TFE are not limited thereto.

The encapsulation layer TFE may further include a thin film containing an aluminum oxide (AlOₓ) in order to improve the encapsulation efficiency of the encapsulation layer TFE. The thin film containing an aluminum oxide may be disposed on the upper surface of the encapsulation layer TFE facing the optical functional layer OFL and/or the lower surface of the encapsulation layer TFE facing the light emitting element layer LDL.

The thin film containing the aluminum oxide may be formed through atomic layer deposition (ALD). However, the invention is not limited thereto and the encapsulation layer TFE may further include a thin film made of at least one of various materials suitable for improving the encapsulation efficiency.

In an embodiment, the optical functional layer OFL is disposed on the encapsulation layer TFE and may include a color filter layer CFL and a lens array LA. The color filter layer CFL is disposed between the encapsulation layer TFE

and the lens array LA. The color filter layer CFL is configured to selectively output light in a wavelength range or color corresponding to each sub-pixel by filtering light emitted from the light emitting structure EMS. The color filter layer CFL includes color filters CF respectively corresponding to the sub-pixels SP1 to SP3, and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light emitting structure EMS of each sub-pixel.

In an embodiment, the lens array LA is disposed on the color filter layer CFL. The lens array LA may include lenses LS respectively corresponding to the sub-pixels SP1 to SP3. Each of the lenses LS may improve light output efficiency by outputting light emitted from the light emitting structure EMS in an intended path. The lens array LA may have a relatively high refractive index. For example, the lens array LA may have a higher refractive index than the overcoat layer OC. In an embodiment, the lenses LS may include an organic material. In an embodiment, the lenses LS may include an acrylic material. However, the material of the lenses LS is not limited thereto.

In an embodiment, compared to the opening OP of the pixel defining film PDL, at least some of the color filters CF of the color filter layer CF and at least some of the lenses LS of the lens array LA may be shifted in a direction parallel to a plane defined by the directions DR1 and DR2. Specifically, in the center area of the display area DA, the center of the color filter and the center of the lens may be aligned or overlapped with the center of the opening OP of the corresponding pixel defining film PDL when viewed in the third direction DR3. For example, in the central area of the display area DA, the opening OP of the pixel defining film PDL may completely overlap the corresponding color filter of the color filter layer CF and the corresponding lens of the lens array LA. In an area of the display area DA disposed adjacent to the non-display area NDA, the center of the color filter and the center of the lens may be shifted in a planar direction from the center of the opening OP of the corresponding pixel defining film PDL when viewed in the third direction DR3. For example, in an area of the display area DA disposed adjacent to the non-display area NDA, the opening OP of the pixel defining film PDL may partially overlap the corresponding color filter of the color filter layer CFL and the corresponding lens of the lens array LA. Accordingly, in the center of the display area DA, light emitted from the light emitting structure EMS may be efficiently outputted in the normal direction of the display surface. Light emitted from the light emitting structure EMS at the outside of the display area DA may be efficiently outputted in a direction inclined by a predetermined angle with respect to the normal direction of the display surface.

In an embodiment, the overcoat layer OC may be disposed on the lens array LA and may cover the optical functional layer OFL, the encapsulation layer TFE, the light emitting structure EMS, and/or the pixel circuit layer PCL. The overcoat layer OC may include various materials suitable for protecting lower layers thereof from foreign substances such as dust and moisture. For example, the overcoat layer OC may include at least one of an inorganic insulating film and an organic insulating film. For example, the overcoat layer OC may include an epoxy resin, but the invention is not limited thereto.

The overcoat layer OC may have a lower refractive index than the lens array LA.

In an embodiment, the cover window CW may be disposed on the overcoat layer OC and is configured to protect lower layers thereof. The cover window CW may have a higher refractive index than the overcoat layer OC. The cover window CW may include glass, but the invention is not limited thereto. For example, the cover window CW may be an encapsulation glass configured to protect constituent elements disposed thereunder. In other embodiments, the cover window CW may be omitted.

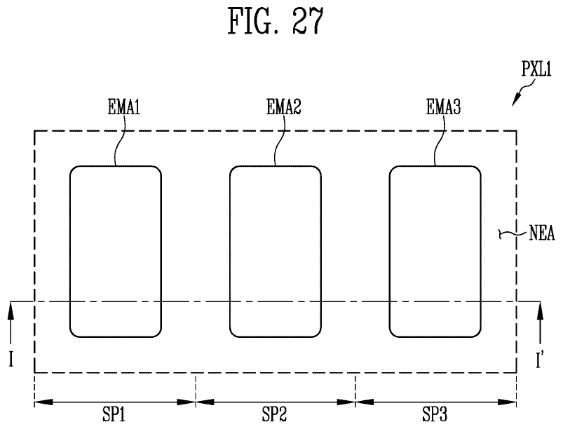

FIG. 27 illustrates a top plan view of one of the pixels of FIG. 26, according to an embodiment.

For a clear and concise description in FIG. 27, the first pixel PXL1 among the pixels PXL1 and PXL2 of FIG. 26 is schematically illustrated. The remaining pixels may be configured similarly to the first pixel PXL1.

In an embodiment and referring to FIG. 26 and FIG. 27, a first pixel PXL1 may include the sub-pixels SP1 to SP3 disposed in the first direction DR1.

The first sub-pixel SP1 may include a first light emitting area EMA1 and a non-light emitting area NEA disposed around the first light emitting area EMA1. The second sub-pixel SP2 may include a second light emitting area EMA2 and a non-light emitting area NEA disposed around the second light emitting area EMA2. The third sub-pixel SP3 may include a third light emitting area EMA3 and a non-light emitting area NEA disposed around the third light emitting area EMA3.

The first light emitting area EMA1 may be an area in which light is emitted from a portion of the light emitting structure EMS (see FIG. 26) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3. As described with reference to FIG. 26, each light emitting area may be understood as the opening OP of the pixel defining film PDL corresponding to each of the sub-pixels SP1 to SP3.

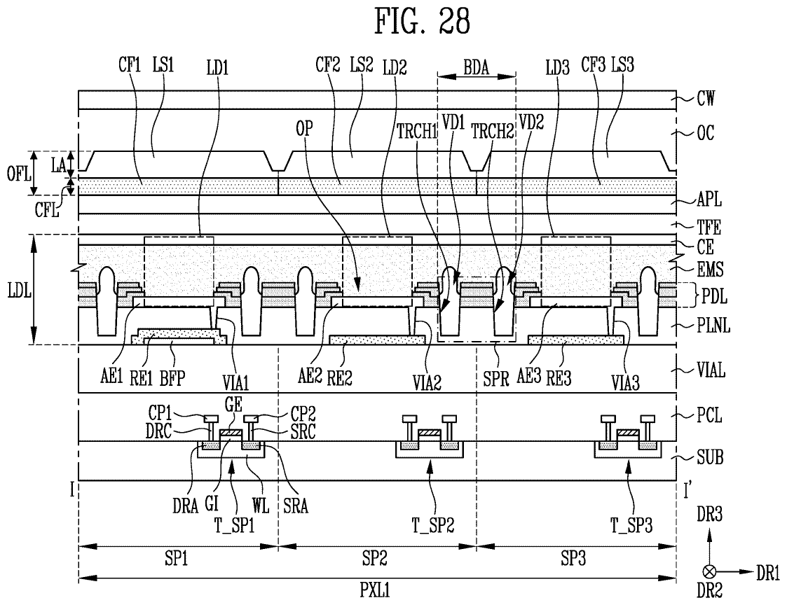

FIG. 28 illustrates a vertical cross-sectional view taken along line I-I′ of FIG. 27, according to an embodiment.

In an embodiment and referring to FIG. 28, a pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

In an embodiment, the pixel circuit layer PCL is disposed on the substrate SUB, where the substrate SUB and the pixel circuit layer PCL may include circuit elements for each of the sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 2) of the first sub-pixel SP1, the transistor T SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 28, for clear and concise description, one of the transistors of each sub-pixel is shown and the remaining circuit elements are omitted.

In an embodiment, the transistor T_SP1 of the first sub-pixel SP1 may include a source area SRA, a drain area DRA, and a gate electrode GE.

The source area SRA and the drain area DRA may be disposed within the substrate SUB. A well WL formed through an ion injection process is disposed in the substrate SUB, and the source area SRA and the drain area DRA may be disposed to be spaced apart from each other within the well WL. The area between the source area SRA and the drain area DRA within the well WL may be defined as a channel area.

The gate electrode GE overlaps the channel area between the source area SRA and the drain area DRA and may be disposed on the pixel circuit layer PCL. The gate electrode GE may be separated from the well WL or the channel area by an insulating material such as a gate insulating layer GI. The gate electrode GE may include a conductive material.

In an embodiment, a plurality of layers included in the pixel circuit layer PCL include insulating layers and conductive patterns disposed between the insulating layers, and the conductive patterns may include first and second conductive patterns CP1 and CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are connected to other circuit elements and/or wires, the transistor T_SP1 of the first sub-pixel SP1 may be provided as one of the transistors of the first sub-pixel SP1.

In an embodiment, each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include circuit elements for each of the sub-pixels SP1 to SP3.

In an embodiment, a via layer VIAL is disposed on the pixel circuit layer PCL. The via layer VIAL covers the pixel circuit layer PCL and may have an overall flat surface. The via layer VIAL is configured to flatten steps on the pixel circuit layer PCL. The via layer VIAL may include at least one of a silicon oxide (SiOₓ), a silicon nitride (SiNₓ), and a silicon carbon nitride (SiCN), but embodiments are not limited thereto.

In an embodiment, the light emitting element layer LDL is disposed on the via layer VIAL. The light emitting element layer LDL may include first to third reflective electrodes RE1 to RE3, respectively, a planarization layer PLNL, first to third anode electrodes AE1 to AE3, respectively, a pixel defining film PDL, a light emitting structure EMS, and a cathode electrode CE.

In an embodiment, the reflective electrodes RE1 to RE3 are disposed in the sub-pixels SP1 to SP3 on the via layer VIAL, respectively. Each of the reflective electrodes RE1 to RE3 may be connected to a circuit element disposed on the pixel circuit layer PCL through a via penetrating the via layer VIAL.

The reflective electrodes RE1 to RE3 may function as full mirrors that reflect light emitted from the light emitting structure EMS toward the display surface (or the cover window CW). The reflective electrodes RE1 to RE3 may include metallic materials suitable for reflecting light. The reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom, but the invention is not limited thereto.

In an embodiment, a connection electrode may be disposed below each of the reflective electrodes RE1 to RE3, where the connection electrode may improve the electrical connection characteristics between the corresponding reflective electrode and the circuit element of the pixel circuit layer PCL. The connection electrode may have a multi-layered structure. The multi-layered structure may include titanium (Ti), a titanium nitride (TiN), a tantalum nitride (TaN), and the like, but embodiments are not limited thereto. In an embodiment, a corresponding reflective electrode may be disposed between the multiple layers of the connecting electrode.

In an embodiment, a buffer pattern BFP may be disposed below at least one of the reflective electrodes RE1 to RE3. The buffer pattern BFP may include an inorganic material such as a silicon carbon nitride, but embodiments are not limited thereto. By disposing the buffer pattern BFP, the height of the corresponding reflective electrode in the third direction DR3 may be adjusted. For example, the buffer pattern BFP may be disposed between the first reflective electrode RE1 and the via layer VIAL to adjust the height of the first reflective electrode RE1.

The reflective electrodes RE1 to RE3 may function as full mirrors, and the cathode electrode CE may function as a half mirror. Light emitted from the light emitting layer of the light emitting structure EMS may be amplified at least partially by reciprocating between the reflective electrode and the cathode electrode CE, and the amplified light may be outputted through the cathode electrode CE. As such, the distance between each reflective electrode and the cathode electrode CE may be understood as the resonance distance for the light emitted from the light emitting layer of the corresponding light emitting structure EMS.

In an embodiment, the first sub-pixel SP1 may have a shorter resonance distance than other sub-pixels due to the buffer pattern BFP. The resonance distance adjusted in this way may allow light of a specific wavelength range (for example, red color) to be effectively and efficiently amplified. Accordingly, the first sub-pixel SP1 may effectively and efficiently output light of the corresponding wavelength range.

In FIG. 28, the buffer pattern BFP is shown to be provided in the first sub-pixel SP1 and not in the second and third sub-pixels SP2 and SP3, respectively. However, the invention is not limited thereto. The buffer pattern BFP may be also be provided in at least one of the sub-pixels SP2 and SP3, so that the resonance distance of at least one of the sub-pixels SP2 and SP3 may be adjusted. For example, the sub-pixels SP1 to SP3 may correspond to red, green, and blue, respectively, and the distance between the first reflective electrode RE1 and the cathode electrode CE may be shorter than the distance between the second reflective electrode RE2 and the cathode electrode CE, and the distance between the second reflective electrode RE2 and the cathode electrode CE may be shorter than the distance between the third reflective electrode RE3 and the cathode electrode CE.

In an embodiment, to planarize the steps between the reflective electrodes RE1 to RE3, the planarization layer PLNL may be disposed on the via layer VIAL and the reflective electrodes RE1 to RE3. The planarization layer PLNL may entirely cover the reflective electrodes RE1 to RE3 and the via layer VIAL and may have a flat surface. In embodiments, the planarization layer PLNL may be omitted.

In an embodiment, the anode electrodes AE1 to AE3 respectively overlapping the reflective electrodes RE1 to RE3 are disposed on the planarization layer PLNL. The anode electrodes AE1 to AE3 may have shapes similar to the light emitting areas EMA1 to EMA3 of FIG. 27 when viewed in the third direction DR3. The anode electrodes AE1 to AE3 are respectively connected to the reflective electrodes RE1 to RE3. The first anode electrode AE1 may be connected to the first reflective electrode RE1 through the first via VIA1 penetrating the planarization layer PLNL. The second anode electrode AE2 may be connected to the second reflective electrode RE2 through the second via VIA2 penetrating the planarization layer PLNL. The third anode electrode AE3 may be connected to the third reflective electrode RE3 through the third via VIA3 penetrating the planarization layer PLNL.

In an embodiment, the anode electrodes AE1 to AE3 may include at least one of transparent conductive materials such as an indium tin oxide (ITO), an indium zinc oxide (IZO), a zinc oxide (ZnOₓ), an indium gallium zinc oxide (IGZO), and an indium tin zinc oxide (ITZO). However, the materials of the anode electrodes AE1 to AE3 are not limited thereto. For example, the anode electrodes AE1 to AE3 may include a titanium nitride.

In an embodiment, insulating layers for adjusting a height of one or more of the anode electrodes AE1 to AE3 may be further provided. The insulating layers may be disposed between one or more of the anode electrodes AE to AE3 and the corresponding reflective electrodes. In this case, the planarization layer PLNL and/or the buffer pattern BFP may be omitted. For example, the sub-pixels SP1 to SP3 may respectively correspond to red, green, and blue, the distance between the first anode electrode AE1 and the cathode electrode CE may be shorter than the distance between the second anode electrode AE2 and the cathode electrode CE, and the distance between the second anode electrode AE2 and the cathode electrode CE may be shorter than the distance between the third anode electrode AE3 and the cathode electrode CE. The pixel defining film PDL is disposed on some of the anode electrodes AE1 to AE3 and the planarization layer PLNL. The pixel defining film PDL may include an opening OP exposing a portion of each of the anode electrodes AE1 to AE3. The opening OP of the pixel defining film PDL may define the light emitting area of each of the sub-pixels SP1 to SP3. As such, the pixel defining film PDL may be disposed in the non-light emitting area NEA of FIG. 27 to define the light emitting areas EMA1 to EMA3 of FIG. 27.

In an embodiment, the pixel defining film PDL may include a plurality of inorganic insulating layers, where each of the plurality of inorganic insulating layers may include at least one of a silicon oxide (SiOₓ) and a silicon nitride (SiNₓ). For example, the pixel defining film PDL may include first to third inorganic insulating layers sequentially stacked, where each of the first to third inorganic insulating layers may include a silicon nitride, a silicon oxide, and a silicon oxynitride. However, the invention is not limited thereto. The inorganic insulating layers may have a step-shaped cross-section in an area disposed adjacent to the opening OP.

In an embodiment, a separator SPR may be provided in the boundary area BDA between the sub-pixels that are disposed adjacent to each other. In other words, the separator SPR may be provided in each of the boundary areas between the sub-pixels SP in FIG. 25.

In an embodiment, the separator SPR may cause a discontinuity to be formed within the light emitting structure EMS in the boundary area BDA. For example, the light emitting structure EMS may be disconnected bent in the boundary area BDA by the separator SPR.

The separator SPR may be provided in or on the pixel defining film PDL, where the pixel defining film PDL may include one or more trenches TRCH1 and TRCH2 which act as the separator SPR in the boundary area BDA. In an embodiment and as shown in FIG. 28, one or more trenches TRCH1 and TRCH2 may penetrate the pixel defining film PDL and may partially penetrate the planarization layer PLNL. In other embodiments, one or more trenches TRCH1 and TRCH2 may penetrate the pixel defining film PDL and the planarization layer PLNL, and may partially penetrate the via layer VIAL. In still other embodiments, one or more trenches TRCH1 and TRCH2 may at least partially penetrate the planarization layer PLNL and/or the via layer VIAL, and a portion of the pixel defining film PDL may be disposed in one or more of the trenches TRCH1 and TRCH2.

FIG. 28 illustrates that two trenches TRCH1 and TRCH2 are provided in the boundary area BDA, according to an embodiment. However, the invention is not limited thereto. For example, in an embodiment, the pixel defining film PDL may include one trench in the boundary area BDA. In another embodiment, the pixel defining film PDL may include three or more trenches in the boundary area BDA.

In an embodiment, due to the trenches TRCH1 and TRCH2, discontinuous portions such as the first void VD1 and the second void VD2 may be formed in the light emitting structure EMS in the boundary area BDA. Some of the plurality of layers stacked in the light emitting structure EMS may be disconnected or may be bent by the voids VD1 and VD2. For example, at least one charge generation layer included in the light emitting structure EMS may be disconnected in the voids VD1, and VD2. As described above, due to the trenches TRCH1 and TRCH2, the portions of the light emitting structure EMS included in the sub-pixels SP1 to SP3 may be at least partially separated.

In FIG. 28, an embodiment is illustrated where the voids VD1 and VD2 are formed in the light emitting structure EMS in the boundary area BDA, but this is only an example, and the invention is not limited thereto. For example, a valley of a concave shape may be formed in the light emitting structure EMS in the boundary area BDA. Depending on the shapes of the trenches TRCH1 and TRCH2, the discontinuities formed in the light emitting structure EMS may vary.

In an embodiment, the light emitting structure EMS may be formed through processes such as vacuum deposition or inkjet printing. In this case, the same materials as the light emitting structure EMS may be disposed on the bottom surfaces of the trenches TRCH1 and TRCH2 adjacent to the via layer VIAL.

In an embodiment, the separator SPR may be variously deformed to allow the light emitting structure EMS to be able to have a discontinuity in the boundary area BDA. In an embodiment, inorganic insulating patterns additionally stacked on the pixel defining film PDL in the boundary area BDA may be provided without the trenches TRCH1 and TRCH2. A width of the uppermost inorganic insulating pattern among the additionally stacked inorganic insulating patterns may be greater than a width of the inorganic insulating pattern disposed directly below the uppermost inorganic insulating pattern. For example, in the boundary area BDA, the inorganic insulating patterns are sequentially stacked from the pixel defining film PDL, and the uppermost third inorganic insulating pattern may have a larger width than the second inorganic insulating pattern. For example, the pixel defining film PDL may have a cross-section of a “T” or “I” shape in the boundary area BDA. Depending on the shape of the pixel defining film PDL, a plurality of layers included in the light emitting structure EMS may be at least partially disconnected or bent in the boundary area BDA.

In an embodiment, the light emitting structure EMS may be disposed on the anode electrodes AE exposed by the opening OP of the pixel defining film PDL. The light emitting structure EMS may fill the opening OP of the pixel defining film PDL and may be disposed entirely across the sub-pixels SP1 to SP3. As described above, the light emitting structure EMS may be at least partially disconnected or bent in the boundary area BDA by the separator SPR. Accordingly, when the display panel DP (see FIG. 25) operates, the current leaking from each of the sub-pixels SP1 to SP3 to the neighboring sub-pixel through the layers included in the light emitting structure EMS may decrease. Accordingly, the light emitting elements LD1 to LD3 may operate with relatively high reliability.

In an embodiment, the cathode electrode CE may be disposed on the light emitting structure EMS, where the cathode electrode CE may be provided commonly for the sub-pixels SP1 to SP3. The cathode electrode CE may function as a half mirror that partially transmits and partially reflects light emitted from the light emitting structure EMS.

In an embodiment, the first anode electrode AE1, the portion of the light emitting structure EMS overlapping the first anode electrode AE1, and the portion of the cathode electrode CE overlapping the first anode electrode AE1 may configure the first light emitting element LD1. The second anode electrode AE2, the portion of the light emitting structure EMS overlapping the second anode electrode AE2, and the portion of the cathode electrode CE overlapping the second anode electrode AE2 may configure the second light emitting element LD2. The third anode electrode AE3, the portion of the light emitting structure EMS overlapping the third anode electrode AE3, and the portion of the cathode electrode CE overlapping the third anode electrode AE3 may configure the third light emitting element LD3.

In an embodiment, the encapsulation layer TFE is disposed on the cathode electrode CE and may prevent oxygen and/or moisture from penetrating into the light emitting element layer LDL.

The optical functional layer OFL is disposed on the encapsulation layer TFE, where the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include a first color filter CF1, a second color filter CF2 and a third color filter CF3, respectively corresponding to the sub-pixels SP1 to SP3. The color filters CF1 to CF3 may pass light in different wavelength ranges. For example, the color filters CF1 to CF3 may pass red, green, and blue colored light, respectively.

In an embodiment, the color filters CF1 to CF3 may partially overlap in the boundary area BDA. In other embodiments, the color filters CF1 to CF3 may be spaced apart from each other, and a black matrix may be provided of between the color filters CF1 to CF3.

In an embodiment, the lens array LA is disposed on the color filter layer CFL and may include a first lens LS1, a second lens LS2 and a third lens LS3 respectively corresponding to the sub-pixels SP1 to SP3. The lenses LS1 to LS3 may improve light output efficiency by outputting the light emitted from the light emitting elements LD1 to LD3, respectively, along an intended path.

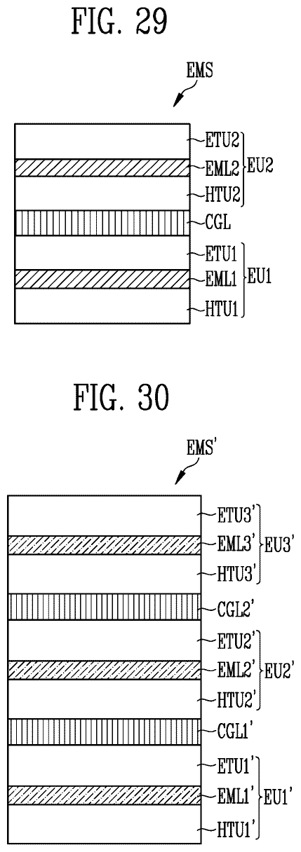

FIG. 29 illustrates a cross-sectional view of the light emitting structure EMS included in one of the light emitting elements LD1 to LD3 of FIG. 28, according to an embodiment.

In an embodiment and referring to FIG. 29, the light emitting structure EMS may have a tandem structure in which light emitting portions EU1 and EU2 are stacked. The light emitting structure EMS′ (see FIG. 30) may be configured to be substantially the same in each of the light emitting elements LD1 to LD3 of FIG. 28.

In an embodiment, each of the light emitting portions EU1 and EU2 may include at least one light emitting layer that generates light according to a current applied thereto. The first light emitting portion EU1 may include a first light emitting layer EML1, a first electron transport portion ETU1, and a first hole transport portion HTU1, where the first light emitting layer EML1 may be disposed between the first electron transport portion ETU1 and the first hole transport portion HTU1. The second light emitting portion EU2 may include a second light emitting layer EML2, a second electron transport portion ETU2, and a second hole transport portion HTU2, where the second light emitting layer EML2 may be disposed between the second electron transport portion ETU2 and the second hole transport portion HTU2.

Each of the hole transport portions HTU1 and HTU2 may include at least one of a hole injection layer and a hole transport layer, and may further include a hole buffer layer, an electron blocking layer, or the like as needed. The hole transport portions HTU1 and HTU2 may have the same configuration or different configurations.

Each of the electron transport portions ETU1 and ETU2 may include at least one of an electron injection layer and an electron transport layer, and may further include an electron buffer layer and a hole blocking layer as needed. The electron transport portions ETU1 and ETU2 may have the same configuration or different configurations. In an embodiment, a connection layer, which may be provided in the form of a charge generation layer CGL, may be disposed between the first light emitting portion EU1 and the second light emitting portion EU2 to connect them to each other. In an embodiment, the charge generation layer CGL may have a stacked structure of a p dopant layer and an n dopant layer. For example, the p dopant layer may include a p-type dopant such as HAT-CN, TCNQ, NDP-9, or the like. The n dopant layer may include an alkali metal, an alkaline-earth metal, a lanthanide-based metal, or a combination thereof. However, the invention is not limited thereto.

In an embodiment, the first light emitting layer EML1 and the second light emitting layer EML2 may generate light of different colors. The light emitted from each of the first light emitting layer EML1 and the second light emitting layer EML2 may be mixed to be recognized as white light. For example, the first light emitting layer EML1 may generate blue-colored light, and the second light emitting layer EML2 may generate yellow-colored light. In an embodiment, the second light-emitting layer EML2 may include a structure in which a first sub-light-emitting layer configured to generate red-colored light and a second sub-light-emitting layer configured to generate green-colored light are stacked. The red-colored light and the green-colored light may be mixed to provide yellow-colored light. In this case, an intermediate layer configured to perform a function of transporting holes and/or preventing transport of electrons may be further disposed between the first and second sub-light emitting layers.

In other embodiments, the first light emitting layer EML1 and the second light emitting layer EML2 may generate light of the same color.

The light emitting structure EMS may be formed through a vacuum deposition method, an inkjet printing method, or the like, but the invention is not limited thereto.

FIG. 30 illustrates a cross-sectional view of a light emitting structure EMS′ included in one of the light emitting elements LD1 to LD3 of FIG. 28, according to an embodiment.

In an embodiment and referring to FIG. 30, the light emitting structure EMS′ may have a tandem structure in which light emitting portions EU1′ to EU3′ are stacked. The light emitting structure EMS′ may be configured to be substantially the same in each of the light emitting elements LD1 to LD3 of FIG. 28.

In an embodiment, each of the light emitting portions EU1′ to EU3′ may include a light emitting layer that generates light according to a current applied thereto. The first light emitting portion EU1′ may include a first light emitting layer EML1′, a first electron transport portion ETU1′, and a first hole transport portion HTU1′. The first light emitting layer EML1′ may be disposed between the first electron transport portion ETU1′ and the first hole transport portion HTU1′. The second light emitting portion EU2′ may include a second light emitting layer EML2′, a second electron transport portion ETU2′, and a second hole transport portion HTU2′. The second light emitting layer EML2′ may be disposed between the second electron transport portion ETU2′ and the second hole transport portion HTU2′. The third light emitting portion EU3′ may include a third light emitting layer EML3′, a third electron transport portion ETU3′, and a third hole transport portion HTU3′. The third light emitting layer EML3′ may be disposed between the third electron transport portion ETU3′ and the third hole transport portion HTU3.

In an embodiment, each of the hole transport portions HTU1′ to HTU3′ may include at least one of a hole injection layer and a hole transport layer, and may further include a hole buffer layer, an electron blocking layer, or the like as needed. The hole transport portions HTU1′ to HTU3′ may have the same configuration or different configurations.

In an embodiment, each of the electron transport portions ETU1′ to ETU3′ may include at least one of an electron injection layer and an electron transport layer, and may further include an electron buffer layer and a hole blocking layer as needed. The first to third electron transport portions ETU1′ to ETU3′ may have the same configuration or different configurations.

In an embodiment, a first charge generation layer CGL1′ may be disposed between the first light emitting portion EU1′ and the second light emitting portion EU2′. A second charge generation layer CGL2′ may be disposed between the second light emitting portion EU2′ and the third light emitting portion EU3′.

In an embodiment, the light emitting layers EML1′ to EML3′ may generate light of different colors. Light emitted from each of the light emitting layers EML1′ to EML3′ may be mixed to be viewed as white light. For example, the first light emitting layer EML1′ may generate light of a blue color, the second light emitting layer EML2′ may generate light of a green color, and the third light emitting layer EML3′ may generate light of a red color.

In other embodiments, two or more of the light emitting layers EML1′ to EML3′ may generate light of the same color.

Unlike the embodiments shown in FIG. 29 and FIG. 30, the light emitting structure EMS in the embodiment of FIG. 28 may include one light emitting portion in each of the light emitting elements LD1 to LD3. In this case, the light emitting portions respectively included in the light emitting elements LD1 to LD3 may be configured to emit light of different colors. For example, the light emitting portion of the first light emitting element LD1 may emit red-colored light, the light emitting portion of the second light emitting element LD2 may emit green-colored light, and the light emitting portion of the third light emitting element LD3 may emit blue-colored light. In this case, unlike that shown in FIG. 28, the light emitting portions of the sub-pixels SP1 to SP3 are separated from each other, and each of them may be disposed in the opening OP of the pixel defining film PDL. In this case, at least some of the color filters CF1 to CF3 may be omitted.

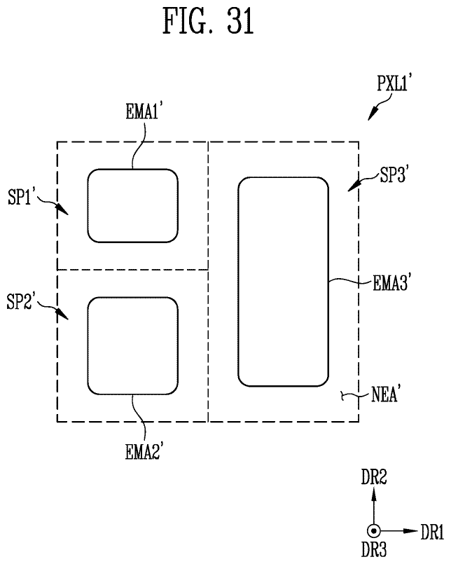

FIG. 31 illustrates a top plan view of one of pixels of FIG. 26, according to another embodiment.

In an embodiment and referring to FIG. 31, a first pixel PXL1′ may include first to third sub-pixels SP1′ to SP3′.

The first sub-pixel SP1′ may include a first light emitting area EMA1′ and a non-light emitting area NEA′ around the first light emitting area EMA1′. The second sub-pixel SP2′ may include a second light emitting area EMA2′ and a non-light emitting area NEA′ around the second light emitting area EMA2′. The third sub-pixel SP3′ may include a third light emitting area EMA3′ and a non-light emitting area NEA′ around the third light emitting area EMA3′.

The first sub-pixel SP1′ and the second sub-pixel SP2′ may be disposed in the second direction DR2. The third sub-pixel SP3′ may be disposed in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second light emitting area EMA2′ may have a larger area than the first light emitting area EMA1′, and the third light emitting area EMA3′ may have a larger area than the second light emitting area EMA2′. However, the invention is not limited thereto. For example, in an embodiment, the sub-pixels SP1′ and SP2′ may have substantially the same area, and the third sub-pixel SP3′ may have a larger area than each of the sub-pixels SP1′ and SP2′. As such, the areas of the sub-pixels SP1′ to SP3′ may be variously changed depending on embodiments.

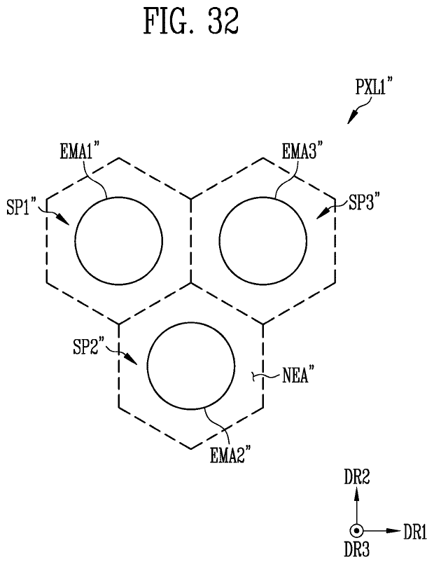

FIG. 32 illustrates a top plan view of one of pixels of FIG. 26, according to another embodiment.

In an embodiment and referring to FIG. 32, the first sub-pixel SP1″ may include a first light emitting area EMA1″ and a non-light emitting area NEA″ around the first light emitting area EMA1″. The second sub-pixel SP2″ may include a second light emitting area EMA2″ and a non-light emitting area NEA″ around the second light emitting area EMA2″. The third sub-pixel SP3″ may include a third light emitting area EMA3″ and a non-light emitting area NEA″ around the third light emitting area EMA3″.

The sub-pixels SP1″ to SP3″ may have polygonal shapes when viewed in the third direction DR3. For example, the shapes of the sub-pixels SP1″ to SP3″ may have hexagonal shapes as shown in FIG. 32.

The light emitting areas EMA1″ to EMA3″ may have circular shapes when viewed in the third direction DR3. However, the invention is not limited thereto. For example, each of the light emitting areas EMA1″ to EMA3″ may have a polygonal shape.

The sub-pixels SP1″ and SP3″ may be disposed in the first direction DR1. The second sub-pixel SP2″ may be disposed in a direction (or a diagonal direction) that is inclined by an acute angle with respect to the second direction DR2 with respect to the first sub-pixel SP1″.

The dispositions of the sub-pixels illustrated in FIGS. 27, 31, and 32 are merely examples, and the invention is not limited thereto

Each pixel may include two or more sub-pixels, the sub-pixels may be variously disposed, each of the sub-pixels may have various shapes, and each of its light emitting areas may also have various shapes.

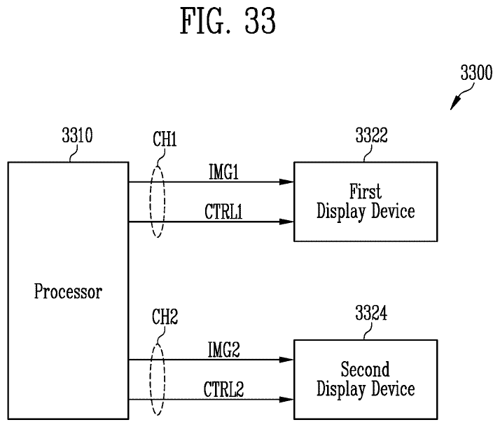

FIG. 33 illustrates a block diagram of a display system 3300, according to an embodiment.

In an embodiment and referring to FIG. 33, the display system 3300 may include a processor 3310 and one or more display devices 3322 and 3324.

The processor 3310 may perform various tasks and calculations. In an embodiment, the processor 3310 may include an application processor (AP), a graphic processing unit (GPU), a microprocessor, a central processing unit (CPU), and the like. The processor 3310 may be connected to and step other constituent elements of the display system 3300 through a bus system.

In FIG. 33, the display system 3300 is shown to include the display devices 3322 and 3324. The processor 3310 may be connected to the first display device 3322 through a first channel CH1 and to the second display device 3324 through a second channel CH2.

Through the first channel CH1, the processor 3310 may transmit first image data IMG1 and a first control signal CTRL1 to the first display device 3322, where the first display device 3322 may display an image based on the first image data IMG1 and the first control signal CTRL1. The first display device 3322 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 3310 may transmit second image data IMG2 and a second control signal CTRL2 to the second display device 3324, where the second display device 3324 may display an image based on the second image data IMG2 and the second control signal CTRL2. The second display device 3324 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 3300 may include a computing system providing image display functions such as a portable computer, a mobile phone, a smart phone, a tablet personal computer (PC), a smart watch, a watch phone, a portable multimedia player (PMP), a navigation system, and an ultra-mobile personal computer (UMPC). In addition, the display system 3300 may include at least one of a head-mounted display device (HMD), a virtual reality (VR) device, a mixed reality (MR) device, and an augmented reality (AR) device.

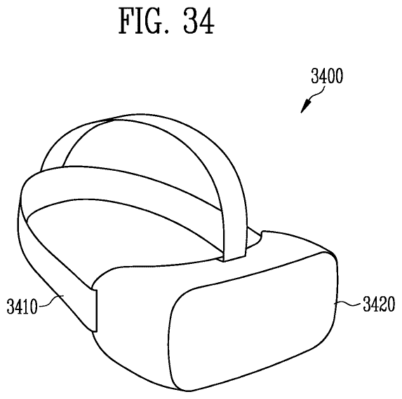

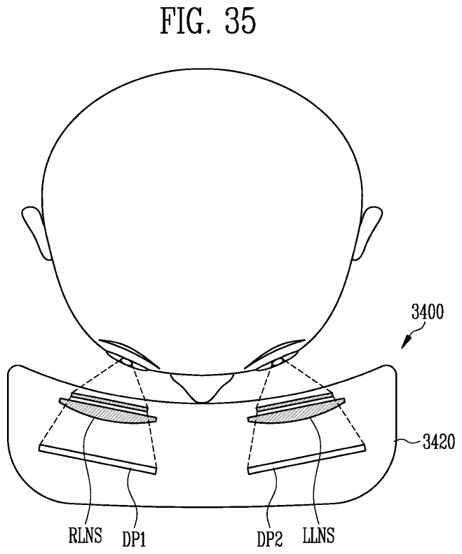

FIG. 34 illustrates a perspective view of an application example of the display system 3300 of FIG. 33, according to an embodiment.

In an embodiment and referring to FIG. 34, the display system 3300 of FIG. 33 may be applied to a head-mounted display device 3400, where the head-mounted display device 3400 may be a wearable electronic device that may be worn on the user's head.

The head-mounted display device 3400 may include a head-mounted band 3410 and a display device accommodation case 3420. The head-mounted band 3410 may be connected to the display device accommodation case 3420. The head-mounted band 3410 may include a horizontal band and/or a vertical band for fixing the head-mounted display device 3400 to the user's head. The horizontal band may be configured to surround the side portion of the user's head, and the vertical band may be configured to surround the upper portion of the user's head. However, the invention is not limited thereto. For example, the head-mounted band 3410 may be implemented in the form of a spectacle frame, a helmet, or the like.

The display device accommodation case 3420 may accommodate the first and second display devices 3322 and 3324 of FIG. 33. The display device accommodation case 3420 may further accommodate the processor 3310 of FIG. 33.

FIG. 35 illustrates a head-mounted display device 3400 worn on a user, according to an embodiment.

In an embodiment and referring further to FIG. 35, a first display panel DP1 of the first display device 3322 and a second display panel DP2 of the second display device 3324 are disposed in the head mounted display device 3400. The head-mounted display device 3400 may further include one or more lenses LLNS and RLNS.

In the display device accommodation case 3420, the right eye lens RLNS may be disposed between the first display panel DP1 and the right eye of the user. In the display device accommodation case 3420, the left eye lens LLNS may be disposed between the second display panel DP2 and the left eye of the user.

An image outputted from the first display panel DP1 may be shown to the right eye of the user through the right eye lens RLNS. The right eye lens RLNS may refract light from the first display panel DP1 to be directed to the right eye of the user. The right eye lens RLNS may perform an optical function to adjust the viewing distance between the first display panel DP1 and the right eye of the user.

An image outputted from the second display panel DP2 may be shown to the left of the user through the left eye lens LLNS. The left eye lens LLNS may refract light from the second display panel DP2 to be directed to the left eye of the user. The left eye lens LLNS may perform an optical function to adjust the viewing distance between the second display panel DP2 and the left eye of the user.

In an embodiment, each of the right eye lens RLNS and the left eye lens LLNS may include an optical lens having a cross-section of a pancake shape. In an embodiment, each of the right eye lens RLNS and the left eye lens LLNS may include a multi-channel lens including sub-areas with different optical characteristics. In this case, each display panel outputs images corresponding to the sub-areas of the multi-channel lens, and the output images may pass through the sub-areas and be viewed by the user.

According to the embodiments disclosure herein, a transistor capable of performing the function of a capacitor may be provided.

Although certain embodiments and implementations have been described herein, other embodiments and modifications will be apparent from this description. Example embodiments have been disclosed herein, and although specific terms are employed, they are used and are to be interpreted in a generic and descriptive sense only and not for purpose of limitation. In some instances, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the invention. Thus, while various embodiments have been described above, those skilled in the art will appreciate that various modifications, additions and substitutions are possible, without departing from the scope and spirit of the invention.

What is claimed is:

1. A sub-pixel comprising:
a light emitting element connected between a first node and a second power line;
a first transistor connected between a first power line and the first node and including a gate connected to a second node;
a second transistor connected to a data line and including a gate connected to a first scan line;
a third transistor connected between the first node and the second node and including a gate connected to a second scan line;
a fourth transistor connected between the first node and the light emitting element and including a gate connected to a light emitting control line;
a fifth transistor connected between the fourth transistor and a third power line and including a gate connected to a third scan line;
a sixth transistor including a gate, a source electrode, and a drain electrode, wherein the gate is connected to one of the second transistor and the second node, and the source electrode and the drain electrode are connected to the other of the second transistor and the second node; and
a seventh transistor including a gate, a source electrode, and a drain electrode, wherein the gate is connected to one of the second node and a fourth power line, and the source electrode and the drain electrode are connected to the other of the second node and the fourth power line.

2. The sub-pixel of claim 1, wherein
the first transistor, the second transistor, the third transistor, the fourth transistor and the fifth transistor include a P-type semiconductor layer.

3. The sub-pixel of claim 2, wherein
the sixth transistor includes a P-type semiconductor layer.

4. The sub-pixel of claim 2, wherein
the sixth transistor includes an N-type semiconductor layer.

5. The sub-pixel of claim 2, wherein
the seventh transistor includes a P-type semiconductor layer.

6. The sub-pixel of claim 2, wherein
the seventh transistor includes an N-type semiconductor layer.

7. The sub-pixel of claim 1, wherein
each of the first transistor, the second transistor, the third transistor, the fourth transistor, the fifth transistor, the sixth transistor and the seventh transistor includes a semiconductor layer formed on a silicon substrate.

8. The sub-pixel of claim 7, wherein
a thickness of a gate insulating layer disposed between the gate of the first transistor and the semiconductor layer of the first transistor is thicker than that of a gate insulating layer disposed between the gate of at least one of the second transistor, the third transistor, the fourth transistor, the fifth transistor, the sixth transistor and the seventh transistor and the semiconductor layer thereof.

9. The sub-pixel of claim 7, wherein
the semiconductor layer of each of the first transistor, the second transistor, the third transistor, the fourth transistor and the fifth transistor is disposed in an N-well.

10. The sub-pixel of claim 9, wherein
the semiconductor layer of each of the sixth transistor and the seventh transistor is disposed in the N-well.

11. The sub-pixel of claim 9, wherein
the semiconductor layer of at least one of the sixth transistor and the seventh transistor is disposed in a P-well.

12. The sub-pixel of claim 11, wherein
the N-well is deeper than the P-well.

13. The sub-pixel of claim 1, wherein
a (1-1)-th power voltage is applied to the first power line, and a second power voltage is applied to the second power line, wherein
a level of the (1-1)-th power voltage is greater than that of the second power voltage.

14. The sub-pixel of claim 13, wherein
a (1-2)-th power voltage that is greater than the second power voltage is applied to the fourth power line.

15. The sub-pixel of claim 13, wherein
an initialization voltage is applied to the third power line and
the fourth power line.

16. A display device comprising:
a display panel including a plurality of sub-pixels disposed on a substrate, wherein the display panel includes a plurality of data lines connected to the plurality of sub-pixels; and
a data driver configured to supply a reference voltage or a data signal to the plurality of data lines,
wherein at least one of the plurality of sub-pixels includes:
a light emitting element connected between a first node and a second power line;
a first transistor connected between a first power line and the first node and including a gate connected to a second node;
a second transistor connected to one of the plurality of data lines and including a gate connected to a first scan line;
a third transistor connected between the first node and the second node and including a gate connected to a second scan line;
a fourth transistor connected between the first node and the light emitting element and including a gate connected to a light emitting control line;
a fifth transistor connected between the fourth transistor and a third power line and including a gate connected to a third scan line;
a sixth transistor including a gate, a source electrode, and a drain electrode, wherein the gate is connected to one of the second transistor and the second node, and wherein the source electrode and the drain electrode are connected to the other of the second transistor and the second node; and
a seventh transistor including a gate, a source electrode, and a drain electrode, wherein the gate is connected to one of the second node and a fourth power line, and wherein the source electrode and the drain electrode are connected to the other of the second node and the fourth power line.

17. The display device of claim 16, wherein
the display panel includes:
a substrate including a semiconductor layer;
a gate insulating layer disposed on the substrate; and
a gate electrode disposed to overlap a channel area of the semiconductor layer,
wherein the gate of each of the first transistor, the second transistor, the third transistor, the fourth transistor, the fifth transistor, the sixth transistor and the seventh transistor includes the gate electrode.

18. The display device of claim 17, wherein
each of the first transistor, the second transistor, the third transistor, the fourth transistor, the fifth transistor, the sixth transistor and the seventh transistor includes a P-type semiconductor layer.

19. The display device of claim 17, wherein
each of the first transistor, the second transistor, the third transistor, the fourth transistor and the fifth transistor and the seventh transistor includes a P-type semiconductor layer, wherein
the sixth transistor includes an N-type semiconductor layer.

20. The display device of claim 17, wherein
each of the first transistor, the second transistor, the third transistor, the fourth transistor, the fifth transistor and the sixth transistor includes a P-type semiconductor layer, wherein
the seventh transistor includes an N-type semiconductor layer.
